(19) United States
(12) Patent Application Publication
(10) Pub. No.: US 2026/0130107 A1
(43) Pub. Date: May 7, 2026

(54) CHIRAL-STRUCTURED HETEROINTERFACES ENABLE DURABLE PEROVSKITE SOLAR CELLS

(71) Applicant: The Hong Kong University of Science and Technology, Hong Kong (CN)

(72) Inventors: Yuanyuan ZHOU, Hong Kong (CN); Tianwei DUAN, Hong Kong (CN)

(21) Appl. No.: 19/204,720

(22) Filed: May 12, 2025

Related U.S. Application Data
(60) Provisional application No. 63/715,017, filed on Nov. 1, 2024.

(51) Int. Cl. H10K 85/50; H10K 30/50; H10K 30/85

(52) U.S. Cl. CPC H10K 85/50; H10K 30/85; H10K 30/50

(57) ABSTRACT

An electronic device including: an electron-transport layer; a chiral interface layer disposed on a surface of the electron-transport layer, wherein the chiral interface layer includes a chiral compound, wherein the chiral compound is substantially enantiomerically pure or racemic; and a perovskite layer disposed on a surface of the chiral interface layer; or an electron-transport layer, wherein the electron-transport layer further includes a chiral compound, wherein the chiral compound is substantially enantiomerically pure or racemic; and a perovskite layer disposed on a surface of the electron-transport layer. The electrical device exhibits improved mechanical failure and chemical degradation relative to electrical devices not including the chiral interface layer or the electron-transport layer further including the chiral compound.

### CROSS-REFERENCE TO RELATED APPLICATIONS

The present application claims priority from U.S. Provisional Patent Application No. 63/715,017, filed on Nov. 1, 2024, which is hereby incorporated by reference in its entirety.

### STATEMENT REGARDING PRIOR DISCLOSURES BY THE INVENTORS OR JOINT INVENTORS UNDER 37 CFR 1.77(b)(6)

Part of the present invention was disclosed in a paper published in Tianwei Duan, et al., Chiral-structured heterointerfaces enable durable perovskite solar cells, Science, Vol. 384, Issue 6698, pg. 878-884, 2024 DOI: doi.org/10.1126/science.ado5172, available online May 24, 2024. This paper is a grace period inventor-originated disclosure disclosed within one year before the filing date of this application and falls within the exceptions defined under 35 USC § 102(b)(1). This paper is hereby incorporated by reference in its entirety.

### TECHNICAL FIELD

The present disclosure generally relates to electronic devices exhibiting improved mechanical and chemical stability and increased photoelectronic efficiency.

### BACKGROUND

Perovskite solar cells (PSCs) have proven to be a highly cost-effective photovoltaic technology with impressive performance. Organic-inorganic halide perovskites (OIHPs), the essential light absorbers in PSCs, have exceptional photophysical properties and compatibility with established commercial manufacturing processes, and certified power-conversion efficiencies (PCEs) of single-junction PSCs as high as 26.1% have been reported. However, an important challenge faced by PSCs for withstanding real-world conditions subject to temperature variations is the relatively low mechanical reliability of their critical interfaces, especially those where the two sides have different coefficients of thermal expansion. For example, temperature variations associated with diurnal cycles—along with the coefficient of thermal expansion mismatch between different device layers—can lead to interfacial sliding, interlayer delamination, and void formation, ultimately resulting in mechanical failure and material degradation in PSCs.

Despite the importance of this problem, there are a limited number of reported efforts specifically targeting interface failures in PSCs. Reported strategies to mitigate thermal-cycling fatigue include exploring thermally stable materials, alleviating interfacial stress, and refining encapsulation methods. Although these strategies help improve the thermal stability of materials, more efforts are needed to address the critical challenges related to mechanical reliability at the heterointerfaces. Functional head and tail groups of any incorporated interfacial layer need to be designed that strengthen the bonding between the charge-transport layer and the OIHP surface and also maintain the carrier transport. Conventionally, in tackling interfacial problems, interface passivation has been used to strengthen the interaction between the charge-transport layer and the OIHP. Organic molecules at the interface can also serve as a barrier against environmental factors to improve chemical stability. However, the impact of interface passivation on the mechanical stability of PSCs remains unclear.

Chiral materials have intriguing optical and electronic properties, but most studies of chiral perovskite materials have focused on applications in optoelectronics and spintronics. Chiral structures in natural, mechanically stable biostructures can adopt the form of spiral or helical microstructures and exhibit outstanding deformation tolerance and dynamic adaptability. Examples include helical DNA and viruses, gyroid structures in butterfly wings, the cholesteric liquid crystal phase in beetle exoskeletons, and eye-distinguishable spiral aloe and seashells. Scientists have also designed artificially chiral archetypal metamaterials with distinctive mechanical properties, such as negative Poisson ratios, as well as an enhanced indentation resistance, fracture toughness, shear modulus, and dynamic energy absorption. The prominent mechanical properties of chiral materials are associated with the helical packing of their subunits. The packing arrangement resembles a mechanical spring, which can deflect or deform under force and restore its original shape when the force is released. However, the mechanical characteristics of chiral materials have been rarely considered for PSC development.

Accordingly, there exists a need in the art to develop improved methods for increasing PSC interfacial stability.

### SUMMARY

In a first aspect, the present disclosure provides an electronic device comprising: an electron-transport layer;
a chiral interface layer disposed on a surface of the electron-transport layer, wherein the chiral interface layer comprises a chiral compound, wherein the chiral compound is substantially enantiomerically pure or racemic; and
a perovskite layer disposed on a surface of the chiral interface layer; or
an electron-transport layer, wherein the electron-transport layer further comprises a chiral compound, wherein the chiral compound is substantially enantiomerically pure or racemic; and
a perovskite layer disposed on a surface of the electron-transport layer.

In certain embodiments, the chiral compound comprises one or more chiral centers, axial chirality, planar chirality, spiro chirality, helical chirality, or a combination thereof.

In certain embodiments, the chiral compound comprises one or more functional groups selected from the group consisting of alcohols, thiols, esters, acyls, thioacyls, amines, amides, ureas, carbamates, aldehydes, ketones, carboxylic acids, esters, carbonates, phosphines, phosphites, phosphates, halides, sulfoxides, sulfones, sulfonamides, and conjugate salts thereof.

In certain embodiments, the chiral compound is a chiral amine or a conjugate salt thereof.

In certain embodiments, the chiral compound is represented by a compound of Formula 1:

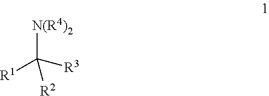

or a conjugate salt thereof, wherein each of R¹, R², and R³ are independently selected from the group consisting of hydrogen, alkyl, haloalkyl, perhaloalkyl, alkenyl, alkynyl, cycloalkyl, heterocycloalkyl, aryl, heteroaryl, and aralkyl; and
R⁴ for each instance is independently selected from the group consisting of hydrogen, alkyl, haloalkyl, perhaloalkyl, alkenyl, alkynyl, cycloalkyl, heterocycloalkyl, aryl, heteroaryl, and aralkyl; or two instances of R⁴ together with the atom they are covalently bonded form a 3-6 membered heterocyloalkyl, wherein R¹, R², and R³ are each different.

In certain embodiments, the chiral compound comprises a salt selected from the group consisting of chloride, bromide, iodide, formate, acetate, propionate, cyanide, cyanate, fulminate, thiocyanate, cyanamide, azide, tetrafluoroborate, hexafluorophosphate, and mixtures thereof.

In certain embodiments, R¹ is hydrogen.

In certain embodiments, R² is alkyl, haloalkyl, perhaloalkyl, alkenyl, or alkynyl; and R³ is alkyl, cycloalkyl, heterocycloalkyl, aryl, heteroaryl, or aralkyl.

In certain embodiments, R¹ is hydrogen; R² is alkyl; and R³ is cycloalkyl, aryl, or heteroaryl; or R¹ is hydrogen; R² is alkyl; and R³ is haloalkyl.

In certain embodiments, R¹ is hydrogen; R² is alkyl; and R³ is aryl; or R¹ is hydrogen; R² is alkyl; and R³ is haloalkyl.

In certain embodiments, R¹ is hydrogen; R² is methyl; and R³ is optionally substituted phenyl; or R¹ is hydrogen; R² is methyl; and R³ is trifluoromethyl.

In certain embodiments, R⁴ is hydrogen.

In certain embodiments, the chiral compound comprises (R)-α-methylbenzylammonium, (S)-α-methylbenzylammonium, (R)-2-ammonium-1,1,1-trifluoropropane, (S)-2-ammonium-1,1,1-trifluoropropane, racemic α-methylbenzylammonium, or racemic 2-ammonium-1,1,1-trifluoropropane.

In certain embodiments, the chiral compound comprises a salt selected from the group consisting of chloride, bromide, iodide, formate, acetate, propionate, cyanide, cyanate, fulminate, thiocyanate, cyanamide, azide, tetrafluoroborate, hexafluorophosphate, and mixtures thereof.

In certain embodiments, the perovskite layer comprises an organic-inorganic halide perovskite having the formula: (A⁺)(M²⁺)(X⁻)₃, wherein M²⁺ comprises Pb²⁺, Sn²⁺, Ge²⁺, or a mixture thereof; X⁻ is F⁻, Cl⁻, Br⁻, I⁻, or a mixture thereof; and A⁺ is Cs⁺, Rb⁺, CH₃NH₃_{⁺}, CH₃CH₂NH₃_{⁺}, H(C═NH₂)NH₂_{⁺}, Me(C═NH₂)NH₂_{⁺}, or a mixture thereof.

In certain embodiments, M²⁺ is Pb²⁺; A⁺ is Cs⁺ and Me(C═NH₂)NH₂_{⁺}; and X⁻ is I⁻.

In certain embodiments, the perovskite layer comprises an organic-inorganic halide perovskite having the formula: FA_{0.9}Cs_{0.1}PbI₃, wherein FA is Me(C═NH₂)NH₂_{^{+.}}

In certain embodiments, the perovskite layer further comprises PbI₂.

In certain embodiments, the electron-transport layer comprises PC₆₁BM, bathocuproine, C₆₀, SnO₂, or a mixture thereof.

In certain embodiments, the chiral compound comprises (R)-α-methylbenzylammonium iodide, (S)-α-methylbenzylammonium iodide, (R)-2-ammonium-1,1,1-trifluoropropane iodide, (S)-2-ammonium-1,1,1-trifluoropropane iodide, racemic α-methylbenzylammonium iodide, or racemic 2-ammonium-1,1,1-trifluoropropane iodide; the perovskite layer comprises an organic-inorganic halide perovskite having the formula: FA₍₁₋ₓ₎CsₓPbI₃, wherein x is 0.01-0.99 and FA is Me(C═NH₂)NH₂_{⁺}; and the electron-transport layer comprises SnO₂.

In certain embodiments, the electronic device further comprises:
a metal electrode disposed on a surface of the electron-transport layer;
a hole-transport layer disposed on a surface of the perovskite layer;
a transparent conductive layer disposed on a surface of the hole-transport layer; and
a substrate layer disposed on a surface of the transparent conductive layer; or
a hole-transport layer disposed on a surface of the perovskite layer;
a transparent conductive layer disposed on a surface of the hole-transport layer;
a substrate layer disposed on a surface of the transparent conductive layer; and
a metal electrode disposed on a surface of the electron-transport layer.

In certain embodiments, the electron-transport layer comprises SnO₂; the hole-transport later comprises N²,N²,N^{2′},N^{2′},N⁷,N⁷,N^{7′},N^{7′}-octakis(4-methoxyphenyl)-9,9′-spirobi[9H-fluorene]-2,2′,7,7′-tetramine (Spiro-OMeTAD), and transparent conductive layer comprises indium tin oxide (ITO).

### BRIEF DESCRIPTION OF DRAWINGS

The above and other objects and features of the present disclosure will become apparent from the following description of the disclosure, when taken in conjunction with the accompanying drawings.

FIG. 1. Schematic of homochiral and heterochiral interface modification. (A) The homochiral perovskite (R-MBA)₂PbI₄ and heterochiral perovskite (R/S-MBA)₂PbI₄ are formed by the reaction of the R-MBAI or R/S-MBAI (1:1 molar ratio of R-MBA⁺ to S-MBA⁺) with excess PbI₂ at the interface of OIHP with ETL. (B) The stacking pattern of the two adjacent organic bilayers is non-colinear in (R-MBA)₂PbI₄ and colinear in (R/S-MBA)₂PbI₄, viewed along the a-axis. In the b-axis direction, (R-MBA)₂PbI₄ and (R/S-MBA)₂PbI₄ have a 2₁ rotational axis containing two benzene rings with π-π stacking of homochiral and heterochiral organic ammonium, respectively. The simple models of R-MBA and S-MBA represent C—H bonds that point straight inward or outward, respectively.

FIG. 2. Mechanical properties of the ETL/OIHP interface. (A) Schematic of the adhesion test and adhesion classification statistics for the perovskite layers on pristine SnO₂, homo-CPI, and hetero-CPI, respectively. A polymethyl methacrylate (PMMA) layer was placed on top of the perovskite layer to prevent epoxy corrosion. A crosscut pattern penetrating through the perovskite to the substrate was made to evaluate the intact part after peeling off the top ITO glass. (B) Classification of adhesion-delamination results for the perovskite layers on pristine SnO₂, homo-CPI, and hetero-CPI, PEAI interface, respectively. There are 20 crosscut sections for each film type. The evaluation was based on the ASTM D3359 standard. (C) Fracture strength statistics for perovskites on pristine SnO₂, homo-CPI, hetero-CPI, and PEAI interface, respectively. (D) Young's modulus statistics for perovskites on pristine SnO₂, homo-CPI, hetero-CPI, and PEAI interface, respectively. The black square is the mean value of the data, and the black diamond is the outlier of the data. (E) Elastic modulus-strength map for perovskites on pristine SnO₂, homo-CPI, hetero-CPI, and PEAI interface, compared to elastomers and polymers. Each material type consists of five samples for the fracture strength and Young's modulus statistics. Data of elastomers and polymers reproduced from ref. 40, AAAS, copyright 2019.

FIG. 3. Electronic properties and chemical stability of the ETL/OIHP interface. (A) The molecule packing models show π-π stacking distance of two R-MBA⁺ molecules (3.76 Å), and R-MBA⁺ and S-MBA⁺ (3.63 Å), for homo-CPI and hetero-CPI, respectively. (B) PL and (C) TRPL of the flipped, delaminated OIHP film exposing the bottom surface on pristine SnO₂, homo-CPI and hetero-CPI. (D) PL and (E) TRPL of the SnO₂/OIHP interface for pristine ETL, homo-CPI, and hetero-CPI from the glass side. (F) The space charge limit current versus voltage of devices on the OIHP/pristine SnO₂ interface, OIHP/R-MBAI-SnO₂, and OIHP/R/S-MBAI-SnO₂. (G) Absorption spectra of OIHP thin films stored in the ambient environment (25° C., 65% RH) on pristine SnO₂, homo-CPI, and hetero-CPI. (H) XRD patterns of the flipped, delaminated OIHP film exposing the bottom surface stored for 3 days in the ambient environment (25° C., 65% RH) on pristine SnO₂, homo-CPI, and hetero-CPI.

FIG. 4. Device performance and stability of PSCs based on pristine SnO₂, homo-CPI, and hetero-CPI. (A) J-V curves of n-i-p PSCs based on pristine SnO₂, homo-CPI, and hetero-CPI. (B) J-V curves of p-i-n PSCs based on pristine SnO₂, homo-CPI, and hetero-CPI. (C) Normalized PCE of encapsulated PSCs based on pristine SnO₂, homo-CPI, and hetero-CPI under 85% RH and 85° C. Initial PCEs for PSCs based on pristine SnO₂, homo-CPI, and hetero-CPI were 21.2%, 23.4%, and 24.1%, respectively. (D) Normalized PCE of n-i-p encapsulated PSCs based on pristine SnO₂, homo-CPI, and hetero-CPI during a temperature cycle test from −40° C. to 85° C. Initial PCEs for PSCs based on pristine SnO₂, homo-CPI, and hetero-CPI were 21.7%, 23.6%, and 24.1%, respectively. (E) Normalized PCE of p-i-n encapsulated PSCs based on pristine SnO₂, homo-CPI, and hetero-CPI during temperature cycle tests from −40° C. to 85° C. Initial PCEs for PSCs based on pristine SnO₂, homo-CPI, and hetero-CPI were 23.8%, 25.3%, and 25.8%, respectively.

FIG. 5. CD spectra of R-MBAI, S-MBAI, R/S-MBAI in ethanol solution.

FIG. 6. (A) XRD pattern of the buried perovskite interface on pristine SnO₂, homo-CPI, and hetero-CPI for n-i-p structured perovskite films, respectively. (B) XRD pattern of samples with elevated concentration of buried chiral molecules for hetero-CPI.

FIG. 7. SEM images of OIHP surface for pristine (A), homo-CPI (B), and hetero-CPI (C), respectively. The crystal size distribution statistic (D) for the three OIHP surfaces.

FIG. 8. SEM images of OIHP bottom for pristine (A), homo-CPI (B), and hetero-CPI (C), respectively. The crystal size distribution statistic (D) for the three OIHP viewed from the bottom side.

FIG. 9. XRD pattern of the pristine and surface-passivated perovskite interface by R-MBAI (Homo-CPI), R/S-MBAI (Hetero-CPI) for p-i-n structured perovskite films, respectively.

FIG. 10. 3D crystal structures for (R-MBA)₂PbI₄ (left), (S-MBA)₂PbI₄ (middle), and (R/S-MBA)₂PbI₄ (right).

FIG. 11. Three 3D crystal models for DFT calculations. (Type I) (R/S-MBA)₂PbI₄ single crystal structure, in which R-MBA⁺ and S-MBA⁺ separately connected to upper and lower inorganic slabs with benzene ring packing; (Type II) Connection of (R-MBA)₂PbI₄ and (S-MBA)₂PbI₄ through (100) plane; (Type III) Connection of (R-MBA)₂PbI₄ and (S-MBA)₂PbI₄ through both (100) and (001) planes. Red shade shows positions for R-MBA⁺, and blue for S-MBA⁺. DFT calculation reveals that energy from type I, II, and III is −266.64 eV/f.u., −266.54 eV/f.u., and −266.42 eV/f.u., respectively.

FIG. 12. 20 Adhesion test images of cross-cut OIHPs areas for pristine (A), homo-CPI (B), hetero-CPI (C), and PEAI interface (D).

FIG. 13. Strain-stress curves of perovskite films on pristine SnO₂ ETL, with homo-CPI, hetero-CPI, and PEAI interface, respectively.

FIG. 14. TRPL of C₆₀/OIHP interface for pristine ETL, homo-CPI, and hetero-CPI from the air side.

FIG. 15. Absorption spectra of OIHP thin films stored in the air (100° C., 20% RH), without light for OIHP thin film on pristine SnO₂, homo-CPI, and hetero-CPI.

FIG. 16. Stabilized power outputs (SPO) of the champion PSC with n-i-p structure based on pristine, homo-CPI and hetero-CPI measured at the maximum power point.

FIG. 17. SPO of the champion PSC with p-i-n structure based on pristine, homo-CPI and hetero-CPI measured at the maximum power point.

FIG. 18. Device parameter statistics, including V_{OC} (A), J_{SC} (B), FF (C), and PCE (D), of 15 individual PSCs based on pristine, homo-CPI and hetero-CPI.

FIG. 19. Normalized PCE of PSCs based on pristine SnO₂, homo-CPI and hetero-CPI under continuous operation under one-sun intensity illumination.

FIG. 20. SEM images for OIHP thin film on pristine SnO₂, homo-CPI, and hetero-CPI, before and after the thermal cycling test. Scale bar: 250 nm.

FIG. 21. Mechanical properties of (PEA)₂PbI₄, (R-MBA)₂PbI₄, and (R/S-MBA)₂PbI₄ films after bending 100 times with a 5 mm radius. (A) SEM images of (PEA)₂PbI₄ before and (B) after bending 100 times. (C) SEM images of (R-MBA)₂PbI₄ before and (D) after bending 100 times. (E) SEM images of (R/S-MBA)₂PbI₄ before and (F) after bending 100 times.

FIG. 22. Device performance, stability, and mechanical properties of the ETL/OIHP interface based on pristine SnO₂, homo-CF₃, and hetero-CF₃. (A) J-V curves with the corresponding PV parameters. (B) PCE statistics (15 PSCs for each device type). (C) Device stability under continuous 1-sun operation. (D) Adhesion test with detached area statistics and (E) strain-stress curves for the perovskite layers on pristine SnO₂, homo-CF₃, and hetero-CF₃.

FIG. 23. Table 1. Classification of delamination test results in ASTM D3359.

FIG. 24. Table 2. The elastic constants (Cᵢⱼ) for (R-MBA)₂PbI₄ and (R/S-MBA)₂PbI₄.

FIG. 25. Table 3. TRPL decay time for Glass/Epoxy/OIHP structured samples.

FIG. 26. Table 4. TRPL decay time for Glass/SnO₂/OIHP structured samples.

FIG. 27. Table 5. TRPL decay time for Glass/OIHP/C₆₀ structured samples.

FIG. 28. (A) depicts an exemplary electronic device (100) comprising: an electron-transport layer (101); a chiral interface layer (102) disposed on a surface of the electron-transport layer (101), wherein the chiral interface layer comprises a chiral compound, wherein the chiral compound is substantially enantiomerically pure or racemic; and a perovskite layer (103) disposed on a surface of the chiral interface layer (102); and (B) an exemplary electronic device (100) comprising: an electron-transport layer (101), wherein the electron-transport layer further comprises a chiral compound, wherein the chiral compound is substantially enantiomerically pure or racemic; and a perovskite layer (103) disposed on a surface of the electron-transport layer (101).

FIG. 29. (A) depicts an exemplary electronic device (200) comprising the electronic device (100) and further comprising: a metal electrode (204) disposed on a surface of the electron-transport layer (201); a hole-transport layer (205) disposed on a surface of the perovskite layer (203); a transparent conductive layer (206) disposed on a surface of the hole-transport layer (205); and a substrate layer (207) disposed on a surface of the transparent conductive layer (206); and (B) an exemplary electronic device (200) comprising the electronic device (100) and further comprising: a hole-transport layer (205) disposed on a surface of the perovskite layer (203); a transparent conductive layer (206) disposed on a surface of the hole-transport layer (205); a substrate layer (207) disposed on a surface of the transparent conductive layer (206); and a metal electrode (204) disposed on a surface of the electron-transport layer (201).

### DETAILED DESCRIPTION

### Definitions

Throughout the application, where compositions are described as having, including, or comprising specific components, or where processes are described as having, including, or comprising specific process steps, it is contemplated that compositions of the present teachings can also consist essentially of, or consist of, the recited components, and that the processes of the present teachings can also consist essentially of, or consist of, the recited process steps.

In the application, where an element or component is said to be included in and/or selected from a list of recited elements or components, it should be understood that the element or component can be any one of the recited elements or components, or the element or component can be selected from a group consisting of two or more of the recited elements or components. Further, it should be understood that elements and/or features of a composition, an apparatus, or a method described herein can be combined in a variety of ways without departing from the spirit and scope of the present teachings, whether explicit or implicit herein

The use of the terms “include,” “includes”, “including,” “have,” “has,” or “having” should be generally understood as open-ended and non-limiting unless specifically stated otherwise.

The use of the singular herein includes the plural (and vice versa) unless specifically stated otherwise. In addition, where the use of the term “about” is before a quantitative value, the present teachings also include the specific quantitative value itself, unless specifically stated otherwise. As used herein, the term “about” refers to a ±10%, ±7%, ±5%, ±3%, ±1%, or ±0% variation from the nominal value unless otherwise indicated or inferred.

It should be understood that the order of steps or order for performing certain actions is immaterial so long as the present teachings remain operable. Moreover, two or more steps or actions may be conducted simultaneously.

As used herein, “halide”, “halo” or “halogen” refers to fluoride/fluoro/fluorine, chloride/chloro/chlorine, bromide/bromo/bromine, and iodide/iodo/iodine.

As used herein, “alkyl” refers to a straight-chain or branched saturated hydrocarbon group. Examples of alkyl groups include methyl (Me), ethyl (Et), propyl (e.g., n-propyl and z′-propyl), butyl (e.g., n-butyl, z′-butyl, sec-butyl, tert-butyl), pentyl groups (e.g., n-pentyl, z′-pentyl, -pentyl), hexyl groups, and the like. In various embodiments, an alkyl group can have 1 to 40 carbon atoms (i.e., C₁-C₄₀ alkyl group), for example, 1-30 carbon atoms (i.e., C₁-C₃₀ alkyl group). In some embodiments, an alkyl group can have 1 to 6 carbon atoms, and can be referred to as a “lower alkyl group.” Examples of lower alkyl groups include methyl, ethyl, propyl (e.g., n-propyl and z′-propyl), and butyl groups (e.g., n-butyl, z′-butyl, sec-butyl, tert-butyl). In some embodiments, alkyl groups can be substituted as described herein. An alkyl group is generally not substituted with another alkyl group, an alkenyl group, or an alkynyl group.

The term “aralkyl” is art-recognized and refers to an alkyl group substituted with an aryl group (e.g., an aromatic or heteroaromatic group).

As used herein, “cycloalkyl” by itself or as part of another substituent means, unless otherwise stated, a monocyclic hydrocarbon having between 3-12 carbon atoms in the ring system and includes hydrogen, straight chain, branched chain, and/or cyclic substituents. Exemplary cycloalkyls include cyclopropyl, cyclobutyl, cyclopentyl, cyclohexyl, cycloheptyl, and the like.

As used herein, “alkenyl” refers to a straight-chain or branched alkyl group having one or more carbon-carbon double bonds. Examples of alkenyl groups include ethenyl, propenyl, butenyl, pentenyl, hexenyl, butadienyl, pentadienyl, hexadienyl groups, and the like. The one or more carbon-carbon double bonds can be internal (such as in 2-butene) or terminal (such as in 1-butene). In various embodiments, an alkenyl group can have 2 to 40 carbon atoms (i.e., C₂-C₄₀ alkenyl group), for example, 2 to 20 carbon atoms (i.e., C₂-C₂₀ alkenyl group). In some embodiments, alkenyl groups can be substituted as described herein. An alkenyl group is generally not substituted with another alkenyl group, an alkyl group, or an alkynyl group.

As used herein, “aryl” refers to an aromatic monocyclic hydrocarbon ring system or a polycyclic ring system in which two or more aromatic hydrocarbon rings are fused (i.e., having a bond in common with) together or at least one aromatic monocyclic hydrocarbon ring is fused to one or more cycloalkyl and/or cycloheteroalkyl rings. An aryl group can have 6 to 24 carbon atoms in its ring system (e.g., C₆-C₂₄ aryl group), which can include multiple fused rings. In some embodiments, a polycyclic aryl group can have 8 to 24 carbon atoms. Any suitable ring position of the aryl group can be covalently linked to the defined chemical structure. Examples of aryl groups having only aromatic carbocyclic ring(s) include phenyl, 1-naphthyl (bicyclic), 2-naphthyl (bicyclic), anthracenyl (tricyclic), phenanthrenyl (tricyclic), pentacenyl (pentacyclic), and like groups. Examples of polycyclic ring systems in which at least one aromatic carbocyclic ring is fused to one or more cycloalkyl and/or cycloheteroalkyl rings include, among others, benzo derivatives of cyclopentane (i.e., an indanyl group, which is a 5,6-bicyclic cycloalkyl/aromatic ring system), cyclohexane (i.e., a tetrahydronaphthyl group, which is a 6,6-bicyclic cycloalkyl/aromatic ring system), imidazoline (i.e., a benzimidazolinyl group, which is a 5,6-bicyclic cycloheteroalkyl/aromatic ring system), and pyran (i.e., a chromenyl group, which is a 6,6-bicyclic cycloheteroalkyl/aromatic ring system). Other examples of aryl groups include benzodioxanyl, benzodioxolyl, chromanyl, indolinyl groups, and the like. In some embodiments, aryl groups can be optionally substituted as described herein. The aryl ring may be substituted at one or more positions with such substituents as described herein, as for example, halogen, alkyl, aralkyl, alkenyl, alkynyl, cycloalkyl, hydroxyl, amino, nitro, sulfhydryl, imino, amido, phosphonate, phosphinate, carbonyl, carboxyl, silyl, ether, alkylthio, sulfonyl, ketone, aldehyde, ester, a heterocyclyl, an aromatic or heteroaromatic moiety, —CF₃, —CN, or the like. In some embodiments, an aryl group can have one or more halogen substituents, and can be referred to as a “haloaryl” group. Perhaloaryl groups, i.e., aryl groups where all of the hydrogen atoms are replaced with halogen atoms (e.g., —C₆F₅), are included within the definition of “haloaryl.” In certain embodiments, an aryl group is substituted with another aryl group and can be referred to as a biaryl group. Each of the aryl groups in the biaryl group can be optionally substituted as disclosed herein.

As used herein, “heteroaryl” refers to an aromatic monocyclic ring system containing at least one ring heteroatom selected from oxygen (O), nitrogen (N), sulfur (S), silicon (Si), and selenium (Se) or a polycyclic ring system where at least one of the rings present in the ring system is aromatic and contains at least one ring heteroatom. Polycyclic heteroaryl groups include those having two or more heteroaryl rings fused together, as well as those having at least one monocyclic heteroaryl ring fused to one or more aromatic carbocyclic rings, non-aromatic carbocyclic rings, and/or non-aromatic cycloheteroalkyl rings. A heteroaryl group, as a whole, can have, for example, 5 to 24 ring atoms and contain 1-5 ring heteroatoms (i.e., 5-20 membered heteroaryl group). The heteroaryl group can be attached to the defined chemical structure at any heteroatom or carbon atom that results in a stable structure. Generally, heteroaryl rings do not contain O—O, S—S, or S—O bonds. However, one or more N or S atoms in a heteroaryl group can be oxidized (e.g., pyridine N-oxide thiophene S-oxide, thiophene S,S-dioxide). Examples of heteroaryl groups include, for example, the 5- or 6-membered monocyclic and 5-6 bicyclic ring systems shown below:

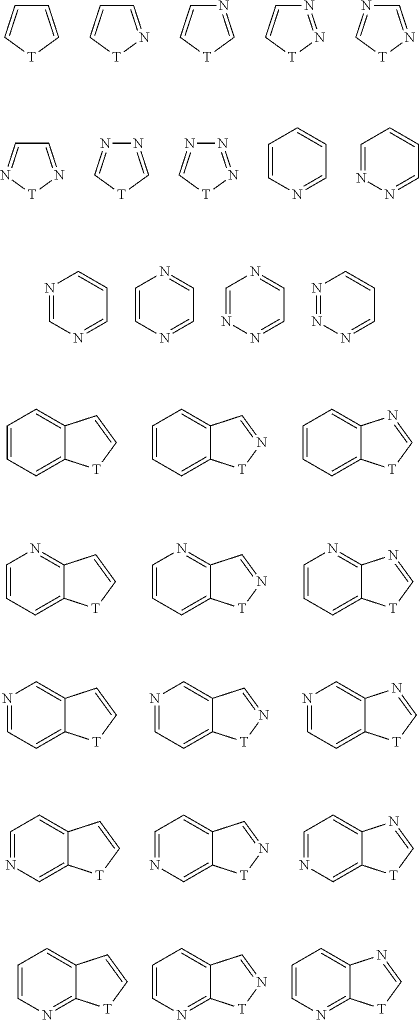

wherein T is O, S, NH, N-alkyl, N-aryl, N-(arylalkyl) (e.g., N-benzyl), SiH₂, SiH(alkyl), Si(alkyl)₂, SiH(arylalkyl), Si(arylalkyl)₂, or Si(alkyl)(arylalkyl). Examples of such heteroaryl rings include pyrrolyl, furyl, thienyl, pyridyl, pyrimidyl, pyridazinyl, pyrazinyl, triazolyl, tetrazolyl, pyrazolyl, imidazolyl, isothiazolyl, thiazolyl, thiadiazolyl, isoxazolyl, oxazolyl, oxadiazolyl, indolyl, isoindolyl, benzofuryl, benzothienyl, quinolyl, 2-methylquinolyl, isoquinolyl, quinoxalyl, quinazolyl, benzotriazolyl, benzimidazolyl, benzothiazolyl, benzisothiazolyl, benzisoxazolyl, benzoxadiazolyl, benzoxazolyl, cinnolinyl, 1H-indazolyl, 2H-indazolyl, indolizinyl, isobenzofuyl, naphthyridinyl, phthalazinyl, pteridinyl, purinyl, oxazolopyridinyl, thiazolopyridinyl, imidazopyridinyl, furopyridinyl, thienopyridinyl, pyridopyrimidinyl, pyridopyrazinyl, pyridopyridazinyl, thienothiazolyl, thienoxazolyl, thienoimidazolyl groups, and the like. Further examples of heteroaryl groups include 4,5,6,7-tetrahydroindolyl, tetrahydroquinolinyl, benzothienopyridinyl, benzofuropyridinyl groups, and the like. In some embodiments, heteroaryl groups can be optionally substituted as described herein. The heterocyclic ring may be substituted at one or more positions with such substituents as described herein, as for example, halogen, alkyl, aralkyl, alkenyl, alkynyl, cycloalkyl, hydroxyl, amino, nitro, sulfhydryl, imino, amido, phosphonate, phosphinate, carbonyl, carboxyl, silyl, ether, alkylthio, sulfonyl, ketone, aldehyde, ester, a heterocyclyl, an aromatic or heteroaromatic moiety, —CF₃, —CN, or the like.

The term “optionally substituted” refers to a chemical group, such as alkyl, cycloalkyl, aryl, heteroaryl, and the like, wherein one or more hydrogen may be replaced with a with a substituent as described herein, for example, halogen, azide, alkyl, aralkyl, alkenyl, alkynyl, cycloalkyl, hydroxyl, alkoxyl, amino, nitro, sulfhydryl, imino, amido, phosphonate, phosphinate, carbonyl, carboxyl, silyl, ether, alkylthio, sulfonyl, sulfonamido, ketone, aldehyde, ester, heterocyclyl, aromatic or heteroaromatic moieties, —CF₃, —CN, or the like.

At various places in the present specification, substituents of compounds are disclosed in groups or in ranges. It is specifically intended that the description include each and every individual sub-combination of the members of such groups and ranges. For example, the term “C₁₋₆ alkyl” is specifically intended to individually disclose C₁, C₂, C₃, C₄, C₅, C₆, C₁-C₆, C₁-C₅, C₁-C₄, C₁-C₃, C₁-C₂, C₂-C₆, C₂-C₅, C₂-C₄, C₂-C₃, C₃-C₆, C₃-C₅, C₃-C₄, C₄-C₆, C₄-C₅, and C₅-C₆ alkyl. By way of other examples, an integer in the range of 0 to 40 is specifically intended to individually disclose 0, 1, 2, 3, 4, 5, 6, 7, 8, 9, 10, 11, 12, 13, 14, 15, 16, 17, 18, 19, 20, 21, 22, 23, 24, 25, 26, 27, 28, 29, 30, 31, 32, 33, 34, 35, 36, 37, 38, 39, and 40, and an integer in the range of 1 to 20 is specifically intended to individually disclose 1, 2, 3, 4, 5, 6, 7, 8, 9, 10, 11, 12, 13, 14, 15, 16, 17, 18, 19, and 20. Additional examples include that the phrase “optionally substituted with 1-4 substituents” is specifically intended to individually disclose a chemical group that can include 0, 1, 2, 3, 4, 0-4, 0-3, 0-2, 0-1, 1-4, 1-3, 1-2, 2-4, 2-3, and 3-4 substituents.

“Enantiomers” are a pair of stereoisomers that are non-superimposable mirror images of each other. A mixture of a pair of enantiomers in equal proportions can be known as a “racemic” mixture. The term “(+/−)” is used to designate a racemic mixture where appropriate. The absolute stereochemistry can be specified according to the Cahn-Ingold-Prelog R-S system. When a compound is an enantiomer, the stereochemistry at each chiral carbon and/or axis of chirality can be specified by either R or S. Resolved compounds whose absolute configuration is unknown can be designated (+) or (−) depending on the direction (dextro- or levorotatory) which they rotate plane polarized light at the wavelength of the sodium D line. Certain compounds described herein can contain one or more asymmetric centers and/or axis of chirality and can thus give rise to enantiomers, diastereomers, and other stereoisomeric forms that can be defined, in terms of absolute stereochemistry at each asymmetric atom or axis of chirality, as (R)- or (S)-. The present compounds and methods are meant to include all such possible isomers, including substantially enantiopure forms and intermediate mixtures. Optically active (R)- and (S)-isomers can be prepared, for example, using chiral synthons or chiral reagents, or resolved using conventional techniques.

The “enantiomeric excess” or “% enantiomeric excess” of a composition can be calculated using the equation shown below. In the example shown below, a composition contains 90% of one enantiomer, e.g., an S enantiomer, and 10% of the other enantiomer, e.g., an R enantiomer. ee=(90−10)/100=80%.

Thus, a composition containing 90% of one enantiomer and 10% of the other enantiomer is said to have an enantiomeric excess of 80%. Some compositions described herein contain an enantiomeric excess of at least about 1%, about 5%, about 10%, about 20%, about 30%, about 40%, about 50%, about 75%, about 90%, about 95%, about 99%, or greater of the S enantiomer. In other words, the compositions contain an enantiomeric excess of the S enantiomer over the R enantiomer. In other embodiments, some compositions described herein contain an enantiomeric excess of at least about 1%, about 5%, about 10%, about 20%, about 30%, about 40%, about 50%, about 75%, about 90%, about 95%, about 99%, or greater of the R enantiomer. In other words, the compositions contain an enantiomeric excess of the R enantiomer over the S enantiomer.

For instance, an enantiomer can, in some embodiments, be provided substantially free of the corresponding enantiomer, and can also be referred to as “optically enriched,” “enantiomerically enriched,” “enantiomerically pure”, “substantially enantiopure” and “non-racemic,” as used interchangeably herein. These terms refer to compositions in which the amount of one enantiomer is greater than the amount of that one enantiomer in a control mixture of the racemic composition (e.g., greater than 1:1 by weight). For example, an enantiomerically enriched preparation of the S enantiomer, means a preparation of the compound having greater than about 50% by weight of the S enantiomer relative to the total weight of the preparation (e.g., total weight of S and R isomers), such as at least about 75% by weight, further such as at least about 80% by weight. In some embodiments, the enrichment can be much greater than about 80% by weight, providing a “substantially enantiomerically enriched,” “substantially enantiomerically pure” or a “substantially non-racemic” preparation, which refers to preparations of compositions which have at least about 70% by weight of one enantiomer relative to the total weight of the preparation, such as at as at least about 75% by weight, such as at as at least about 80% by weight, such as at as at least about 85% by weight, such as at least about 90% by weight, and such as at least about 95% by weight. In certain embodiments, the compound provided herein is made up of at least about 90% by weight of one enantiomer. In other embodiments, the compound is made up of at least about 95%, about 98%, or about 99% by weight of one enantiomer.

In some embodiments, is a mixture of compounds wherein individual compounds of the mixture exist predominately in an (S)- or (R)-isomeric configuration. For example, in some embodiments, the compound mixture has an (S)-enantiomeric excess of greater than about 10%, greater than about 20%, greater than about 30%, greater than about 40%, greater than about 50%, greater than about 55%, greater than about 60%, greater than about 65%, greater than about 70%, greater than about 75%, greater than about 80%, greater than about 85%, greater than about 90%, greater than about 95%, greater than about 96%, greater than about 97%, greater than about 98%, or greater than about 99%. In some embodiments, the compound mixture has an (S)-enantiomeric excess of about 55%, about 60%, about 65%, about 70%, about 75%, about 80%, about 85%, about 90%, about 95%, about 96%, about 97%, about 98%, about 99%, or about 99.5%, or more. In some embodiments, the compound mixture has an (S)-enantiomeric excess of about 55% to about 99.5%, about 60% to about 99.5%, about 65% to about 99.5%, about 70% to about 99.5%, about 75% to about 99.5%, about 80% to about 99.5%, about 85% to about 99.5%, about 90% to about 99.5%, about 95% to about 99.5%, about 96% to about 99.5%, about 97% to about 99.5%, about 98% to about 99.5%, or about 99% to about 99.5%, or more than about 99.5%.

In other embodiments, the compound mixture has an (R)-enantiomeric excess of greater than about 10%, greater than about 20%, greater than about 30%, greater than about 40%, greater than about 50%, greater than about 55%, greater than about 60%, greater than about 65%, greater than about 70%, greater than about 75%, greater than about 80%, greater than about 85%, greater than about 90%, greater than about 95%, greater than about 96%, greater than about 97%, greater than about 98%, or greater than about 99%. In some embodiments, the compound mixture has an (R)-enantiomeric excess of about 55%, about 60%, about 65%, about 70%, about 75%, about 80%, about 85%, about 90%, about 95%, about 96%, about 97%, about 98%, about 99%, or about 99.5%, or more. In some embodiments, the compound mixture has an (R)-enantiomeric excess of about 55% to about 99.5%, about 60% to about 99.5%, about 65% to about 99.5%, about 70% to about 99.5%, about 75% to about 99.5%, about 80% to about 99.5%, about 85% to about 99.5%, about 90% to about 99.5%, about 95% to about 99.5%, about 96% to about 99.5%, about 97% to about 99.5%, about 98% to about 99.5%, or about 99% to about 99.5%, or more than about 99.5%.

Examples of salts of an amino group formed with inorganic acids such as hydrochloric acid, hydrobromic acid, phosphoric acid, sulfuric acid and perchloric acid or with organic acids such as acetic acid, oxalic acid, maleic acid, tartaric acid, citric acid, succinic acid or malonic acid or by using other methods used in the art such as ion exchange. Other salts include adipate, alginate, ascorbate, aspartate, benzenesulfonate, besylate, benzoate, bisulfate, borate, butyrate, camphorate, camphorsulfonate, citrate, cyclopentanepropionate, digluconate, dodecylsulfate, ethanesulfonate, formate, fumarate, glucoheptonate, glycerophosphate, gluconate, hemisulfate, heptanoate, hexanoate, hydroiodide, 2-hydroxy-ethanesulfonate, lactobionate, lactate, laurate, lauryl sulfate, malate, maleate, malonate, methanesulfonate, 2-naphthalenesulfonate, nicotinate, nitrate, oleate, oxalate, palmitate, pamoate, pectinate, persulfate, 3-phenylpropionate, phosphate, picrate, pivalate, propionate, stearate, succinate, sulfate, tartrate, thiocyanate, p-toluenesulfonate, undecanoate, valerate salts, and the like. In certain embodiments, organic acids from which salts can be derived include, for example, acetic acid, propionic acid, glycolic acid, pyruvic acid, oxalic acid, maleic acid, malonic acid, succinic acid, fumaric acid, tartaric acid, citric acid, benzoic acid, cinnamic acid, mandelic acid, methanesulfonic acid, ethanesulfonic acid, p-toluenesulfonic acid, salicylic acid, and the like.

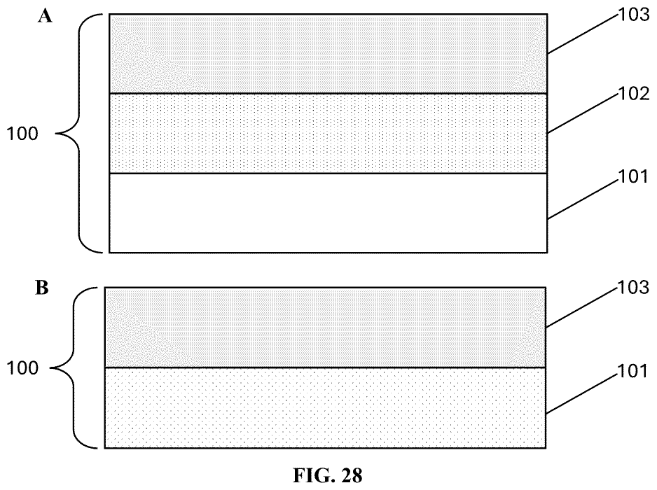

Referring to FIG. 28A, the present disclosure provides an electronic device (100) comprising: an electron-transport layer (101); a chiral interface layer (102) disposed on a surface of the electron-transport layer (101), wherein the chiral interface layer comprises a chiral compound, wherein the chiral compound is substantially enantiomerically pure or racemic; and a perovskite layer (103) disposed on a surface of the chiral interface layer (102); or referring to FIG. 28B, the electronic device (100) comprises: an electron-transport layer (101), wherein the electron-transport layer further comprises a chiral compound, wherein the chiral compound is substantially enantiomerically pure or racemic; and a perovskite layer (103) disposed on a surface of the electron-transport layer (101).

The chiral compound can comprise one or more chiral centers, axial chirality, planar chirality, spiro chirality, helical chirality, or a combination thereof. In certain embodiments, the chiral compound comprises a chiral center.

The chiral compound can comprise one or more functional groups selected from the group consisting of alcohols, thiols, esters, acyls, thioacyls, amines, amides, ureas, carbamates, aldehydes, ketones, carboxylic acids, esters, carbonates, phosphines, phosphites, phosphates, halides, sulfoxides, sulfones, sulfonamides, and conjugate salts thereof. In certain embodiments, the chiral compound comprises a chiral amine or conjugate salt thereof.

In certain embodiments, the chiral compound is represented by a compound of Formula 1:

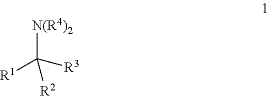

or a conjugate salt thereof, wherein
each of R¹, R², and R³ are independently selected from the group consisting of hydrogen, alkyl, haloalkyl, perhaloalkyl, alkenyl, alkynyl, cycloalkyl, heterocycloalkyl, aryl, heteroaryl, and aralkyl; and
R⁴ for each instance is independently selected from the group consisting of hydrogen, alkyl, haloalkyl, perhaloalkyl, alkenyl, alkynyl, cycloalkyl, heterocycloalkyl, aryl, heteroaryl, and aralkyl; or two instances of R⁴ together with the atom they are covalently bonded form a 3-6 membered heterocyloalkyl, wherein R¹, R², and R³ are each different.

In certain embodiments, R¹ is hydrogen.

R² can be alkyl, haloalkyl, perhaloalkyl, alkenyl, or alkynyl. In certain embodiments, R² is C₁-C₆ alkyl, C₁-C₅ alkyl, C₁-C₄ alkyl, C₁-C₃ alkyl, or C₁-C₂ alkyl. In certain embodiments, R² is CH₃—.

R³ can be haloalkyl, perhaloalkyl, cycloalkyl, heterocycloalkyl, aryl, heteroaryl, or aralkyl. In certain embodiments, R³ is C₃-C₈ cycloalkyl, C₃-C₆ cycloalkyl, C₃-C₅ cycloalkyl, C₅-C₈ cycloalkyl, C₅-C₆ cycloalkyl, C₂-C₆ heterocycloalkyl, C₂-C₄ heterocycloalkyl, C₄-C₅ heterocycloalkyl, C₂-C₆ heterocycloalkyl, C₆-C₁₄ aryl, C₆-C₁₀ aryl, C₄-C₉ heteroaryl, C₄-C₈ heteroaryl, C₄-C₆ heteroaryl, arylCH₂—, arylCH₂CH₂—, C₁-C₆ haloalkyl, C₁-C₅ haloalkyl, C₁-C₄ haloalkyl, C₁-C₃ haloalkyl, C₁-C₂ haloalkyl, C₁-C₆ perhaloalkyl, C₁-C₅ perhaloalkyl, C₁-C₄ perhaloalkyl, C₁-C₃ perhaloalkyl, or C₁-C₂ perhaloalkyl. In certain embodiments, R³ is CFH₂—, CF₂H—, CFH₂CH₂, CF₂CH₂, CF₃CH₂—, CH₃CH_{F}—, CH₃CF₂—, CFH₂CFH—, CF₂HCFH—, CF₃CFH—, CFH₂CF₂—, CF₂HCF₂—, CF₃—, CF₃CF₂—, (CF₃)₂CF₂—, cyclopropyl, cyclobutyl, cyclohexyl, optionally substituted phenyl, optionally substituted napthyl, optionally substituted anthracenyl, optionally substituted biphenyl, optionally substituted pyridinyl, or optionally substituted benzyl. In certain embodiments, R³ is CF₃—, CF₃CF₂—, (CF₃)₂CF₂—, or phenyl optionally substituted with fluorine, chlorine, bromine, iodine, azide, alkyl, aralkyl, alkenyl, alkynyl, cycloalkyl, hydroxyl, alkoxyl, amino, nitro, sulfhydryl, imino, amido, phosphonate, phosphinate, carbonyl, carboxyl, silyl, ether, alkylthio, sulfonyl, sulfonamido, ketone, aldehyde, ester, heterocyclyl, aromatic or heteroaromatic moieties, —CF₃, or —CN.

In certain embodiments, R⁴ is hydrogen.

In certain embodiments, R¹ is hydrogen; R² is methyl; and R³ is CF₃—, CF₃CF₂—, (CF₃)₂CF₂—, or phenyl optionally substituted with fluorine, chlorine, bromine, iodine, azide, alkyl, aralkyl, alkenyl, alkynyl, cycloalkyl, hydroxyl, alkoxyl, amino, nitro, sulfhydryl, imino, amido, phosphonate, phosphinate, carbonyl, carboxyl, silyl, ether, alkylthio, sulfonyl, sulfonamido, ketone, aldehyde, ester, heterocyclyl, aromatic or heteroaromatic moieties, —CF₃, or —CN.

In instances in which the compound of Formula 1 exists as a conjugate salt, the chiral compound can be represented by a compound of Formula 2:

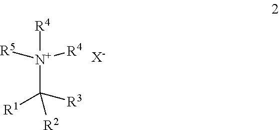

wherein each of R¹, R², R³, R⁴ is independently as defined in any embodiment or combination of embodiments described herein; R⁵ is hydrogen; and X⁻ is an anion. In alternative embodiments, the compound of Formula 2 is ammonium salt in which each of R¹, R², R³, R⁴ is independently as defined in any embodiment or combination of embodiments described herein; R⁵ is methyl or ethyl; and X⁻ is an anion.

The anion X⁻ is not particularly limited and the current disclosure contemplates all anions. In certain embodiments, X⁻ is selected from the group consisting of chloride, bromide, iodide, formate, acetate, propionate, cyanide, cyanate, fulminate, thiocyanate, cyanamide, azide, tetrafluoroborate, hexafluorophosphate, and mixtures thereof. In certain embodiments, X⁻ is iodide.

In certain embodiments, the chiral compound is represented by the compound of Formula 2, wherein R¹ is hydrogen; R² is methyl; R³ is CF₃—, CF₃CF₂—, (CF₃)₂CF₂—, or phenyl optionally substituted with fluorine, chlorine, bromine, iodine, azide, alkyl, aralkyl, alkenyl, alkynyl, cycloalkyl, hydroxyl, alkoxyl, amino, nitro, sulfhydryl, imino, amido, phosphonate, phosphinate, carbonyl, carboxyl, silyl, ether, alkylthio, sulfonyl, sulfonamido, ketone, aldehyde, ester, heterocyclyl, aromatic or heteroaromatic moieties, —CF₃, or —CN; R⁴ is hydrogen; R⁵ is hydrogen; and X is selected from the group consisting of chloride, bromide, iodide, formate, acetate, propionate, cyanide, cyanate, fulminate, thiocyanate, cyanamide, azide, tetrafluoroborate, hexafluorophosphate, and mixtures thereof.

Exemplary chiral compounds useful in the in electronic device described herein include, but are not limited to, salts of (R)-α-methylbenzylammonium, (S)-α-methylbenzylammonium, (R)-2-ammonium-1,1,1-trifluoropropane, (S)-2-ammonium-1,1,1-trifluoropropane, racemic α-methylbenzylammonium, or racemic 2-ammonium-1,1,1-trifluoropropane, wherein the salt comprises an anion selected from the group consisting of chloride, bromide, iodide, formate, acetate, propionate, cyanide, cyanate, fulminate, thiocyanate, cyanamide, azide, tetrafluoroborate, hexafluorophosphate, and mixtures thereof. In certain embodiments, the chiral compound comprises: (R)-α-methylbenzylammonium, (S)-α-methylbenzylammonium iodide, (R)-2-ammonium-1,1,1-trifluoropropane iodide, (S)-2-ammonium-1,1,1-trifluoropropane iodide, racemic α-methylbenzylammonium iodide, or racemic 2-ammonium-1,1,1-trifluoropropane iodide.

The perovskite layer can comprise an organic-inorganic halide perovskite having the formula: (A⁺)(M²⁺)(X⁻)₃, wherein M²⁺ comprises Pb²⁺, Sn²⁺, Ge²⁺, or a mixture thereof; X⁻ is F⁻, Cl⁻, Br⁻, I⁻, or a mixture thereof; and A⁺ is Cs⁺, Rb⁺, CH₃NH₃_{⁺}, CH₃CH₂NH₃_{⁺}, H(C═NH₂)NH₂_{⁺}, Me(C═NH₂)NH₂_{⁺}, or a mixture thereof.

In certain embodiments, M²⁺ is Pb²⁺.

In certain embodiments, M²⁺ is Pb²⁺; A⁺ is Cs⁺ and Me(C═NH₂)NH₂_{⁺}; and X⁻ is I⁻. In certain embodiments, the organic-inorganic halide perovskite is represented by the formula: FA₍₁₋ₓ₎ CsₓPbI₃, wherein x is 0.01-0.99, 0.1-0.99, 0.2-0.99, 0.3-0.99, 0.4-0.99, 0.5-0.99, 0.6-0.99, 0.7-0.99, 0.8-0.99, 0.9-0.99, 0.01-0.9, 0.01-0.8, 0.01-0.7, 0.01-0.6, 0.01-0.6, 0.01-0.5, 0.01-0.4, 0.01-0.3, 0.01-0.2, or 0.85-0.95 and FA is Me(C═NH₂)NH₂_{⁺}. In certain embodiments, the organic-inorganic halide perovskite is represented by the formula: FA_{0.9}Cs_{0.1}PbI₃, wherein FA is Me(C═NH₂)NH₂_{⁺}.

The organic-inorganic halide perovskite can further comprises a second perovskite represented by the formula: (A′⁺)(M′²⁺)(X⁻)₃, wherein M′²⁺ is Pb²⁺, Sn²⁺, or Ge²⁺; each of A⁺, A′⁺, and A′⁺ is independently Cs⁺, Rb⁺, CH₃NH₃_{⁺}, CH₃CH₂NH₃_{⁺}, H(C═NH₂)NH₂_{⁺}, or Me(C═NH₂)NH₂_{⁺}; and X⁻ for each instance is independently F⁻, Cl⁻, Br⁻, or I⁻. In certain embodiments, the second perovskite is MAPbCl₃, wherein MA is CH₃NH₃_{⁺}.

In instances in which the organic-inorganic halide perovskite further comprises the second perovskite, the organic-inorganic halide perovskite can be represented by the Formula 3:

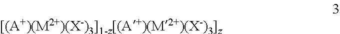

z is 0.01-0.99;
M²⁺ is Pb²⁺, Sn²⁺, or Ge²⁺;
M′²⁺ is Pb²⁺, Sn²⁺, or Ge²⁺;
each of A⁺ and A′⁺ is independently Cs⁺, Rb⁺, CH₃NH₃_{⁺}, CH₃CH₂NH₃_{⁺}, H(C═NH₂)NH₂_{⁺}, Me(C═NH₂)NH₂_{⁺}, or a mixture thereof; and
X⁻ for each instance is independently F⁻, Cl⁻, Br⁻, or I⁻.

In certain embodiments, z is 0.1-0.99, 0.2-0.99, 0.3-0.99, 0.4-0.99, 0.5-0.99, 0.6-0.99, 0.7-0.99, 0.8-0.99, 0.9-0.99, 0.01-0.9, 0.01-0.8, 0.01-0.7, 0.01-0.6, 0.01-0.5, 0.01-0.4, 0.01-0.3, 0.01-0.2, 0.01-0.1, 0.01-0.09, 0.01-0.08, 0.01-0.07, 0.01-0.06, 0.01-0.05, 0.01-0.04, 0.01-0.03, 0.01-0.02, 0.02-0.08, 0.03-0.07, or 0.04-0.06. In certain embodiments, z is about 0.05.

In certain embodiments, the organic-inorganic halide perovskite of Formula 3 is (FAPbI₃)_{0.95}(MAPbBr₃)_{0.05}, wherein FA is Me(C═NH₂)NH₂_{⁺} and MA is CH₃NH₃_{⁺}.

In certain embodiments, the perovskite layer and/or the chiral interface layer or the electron-transport layer further comprises PbI₂. In instances in which the chiral interface layer further comprises PbI₂, at least a portion of the PbI₂ in the chiral interface layer can be present in the form (Q)₂PbI₂, wherein Q represents the compound of Formula 2. In certain embodiments, Q is (R)-α-methylbenzylammonium, (S)-α-methylbenzylammonium iodide, (R)-2-ammonium-1,1,1-trifluoropropane iodide, (S)-2-ammonium-1,1,1-trifluoropropane iodide, racemic α-methylbenzylammonium iodide, or racemic 2-ammonium-1,1,1-trifluoropropane iodide.

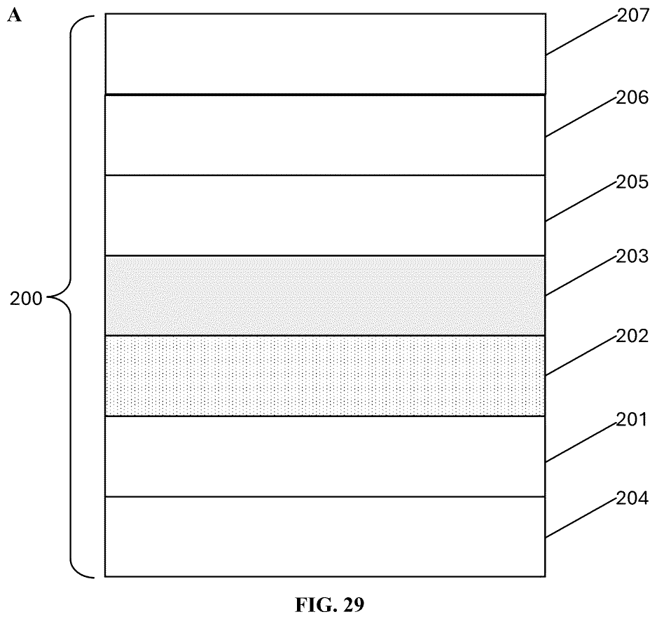

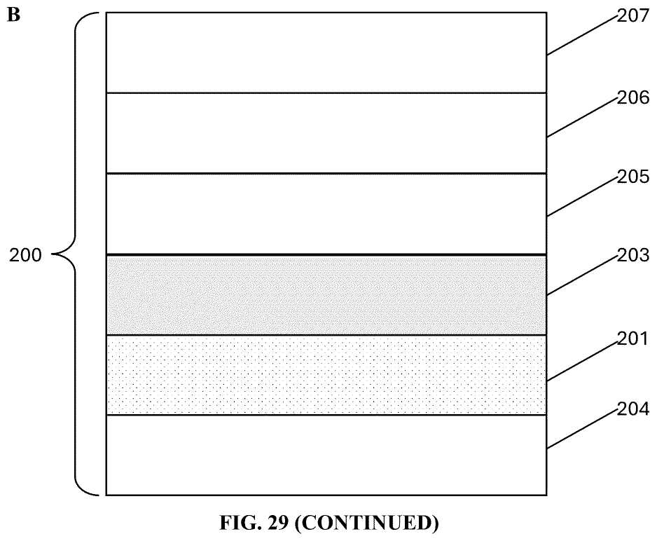

As illustrated in FIG. 29A, the present disclosure also provides the electronic device described herein further comprising: a metal electrode (204) disposed on a surface of the electron-transport layer (201); a hole-transport layer (205) disposed on a surface of the perovskite layer (203); a transparent conductive layer (206) disposed on a surface of the hole-transport layer (205); and a substrate layer (207) disposed on a surface of the transparent conductive layer (206); or as illustrated in FIG. 29B, a hole-transport layer (205) disposed on a surface of the perovskite layer (203); a transparent conductive layer (206) disposed on a surface of the hole-transport layer (205); a substrate layer (207) disposed on a surface of the transparent conductive layer (206); and a metal electrode (204) disposed on a surface of the electron-transport layer (201).

The electron-transport layer (201) can comprise the electron-transport layer comprises PC₆₁BM, bathocuproine, C₆₀, SnO₂, or a mixture thereof. In certain embodiments, the electron-transport layer (201) comprises SnO₂.

The perovskite functional layer (203) comprises the organic-inorganic hybrid perovskite described herein. In certain embodiments, the perovskite layer (203) comprises the organic-inorganic halide perovskite represented by the formula: (FAPbI₃)_{0.95}(MAPbBr₃)_{0.05} or FA_{0.9}Cs_{0.1}PbI₃, wherein FA is Me(C═NH₂)NH₂_{⁺} and MA is CH₃NH₃_{⁺}.

The metal electrode (204) can comprise Ag, Cu, Au, Al, W, Fe, Pt, and mixtures thereof. In certain embodiments, the metal electrode (204) comprises Ag.

The hole-transport layer (205) can comprise a SAM (self-assembled monolayer), PTAA (poly (triaryl amine)), (2-(3,6-dimethoxy-9H-carbazol-9-yl)ethyl)phosphonic acid (MeO-2PACz), poly(3,4-ethylenedioxythiophene):polystyrene sulfonate (PEDOT:PSS), NiOₓ, N²,N²,N^{2′},N^{2′},N⁷,N⁷,N^{7′},N^{7′}-octakis(4-methoxyphenyl)-9,9′-spirobi[9H-fluorene]-2,2′,7,7′-tetramine (Spiro-OMeTAD), or mixtures thereof, wherein x is 1-2. In certain embodiments, the hole-transport layer (205) comprises Spiro-OMeTAD.

The transparent conductive layer (206) can comprise aluminum- or indium-doped zinc oxide, magnesium-indium oxide, nickel-tungsten oxide, gallium nitride, zinc selenide, zinc sulfide, zinc oxide (ZnO), tin oxide (SnO₂), lithium fluoride (LiF), zinc indium tin oxide (ZITO), indium tin oxide (ITO), aluminum zinc oxide (AZO), fluorine tin oxide (FTO), graphene, poly(3,4-ethylenedioxythiophene) polystyrene sulfonate (PEDOT:PSS), silver nanowire, copper nanowire, or a mixture thereof. In certain embodiments, the transparent conductive layer (206) comprises ITO.

The substrate (207) can comprise a flexible or rigid material with light transmittance greater than 80% (at 550 nm). In certain embodiments, the substrate comprises: polymethyl methacrylate (PMMA), polycarbonate (PC), polystyrene, (PS), polyethylene glycol terephthalate, (PET), polyethylene naphthalate (PEN), polydimethylsiloxane (PDMS), styrene-ethylene-butylene-styrene (SEBS), ethylene terephthalateco-1,4-cylclohexylenedimethylene terephthalate (PETG), acrylonitrile butadiene styrene copolymers (ABS), polypropylene (PP), polyamide (PA) acrylonitrile-styrene copolymer (AS), or mixtures thereof.

The present disclosure also provides a method of preparing the electronic device described herein, the method comprising depositing a chiral compound solution comprising the chiral compound and a first solvent on the surface of the electron-transport layer thereby forming an uncured chiral interface layer comprising the chiral compound and the first solvent; removing the first solvent from the uncured chiral interface layer thereby forming the chiral interface layer; depositing a perovskite precursor solution on the surface of the chiral interface layer thereby forming an uncured perovskite layer, wherein the perovskite precursor solution comprises one or more metal salts each independently represented by the formula MX₂, two or more salts each independently represented by the formula AZ, and a second solvent, wherein M is Pb²⁺, Sn²⁺, or Ge²⁺, A is Cs⁺, Rb⁺, CH₃NH₃_{⁺}, CH₃CH₂NH₃_{⁺}, H(C═NH₂)NH₂_{⁺}, or Me(C═NH₂)NH₂_{⁺}, X for each instance is independently F⁻, Cl⁻, Br⁻, or I⁻, and Z for each instance is independently F⁻, Cl⁻, Br⁻, or I⁻; and removing the second solvent from the uncured perovskite layer thereby forming the perovskite layer; or depositing a mixture comprising an electron-transport layer material, the chiral compound, and a third solvent on the surface of the metal electrode thereby forming an uncured electron-transport layer; removing the third solvent from the uncured electron-transport layer thereby forming the electron-transport layer; depositing a perovskite precursor solution on the electron-transport layer thereby forming an uncured perovskite layer, wherein the perovskite precursor solution comprises one or more metal salts each independently represented by the formula MX₂, two or more salts each independently represented by the formula AZ, and a second solvent, wherein M is Pb²⁺, Sn²⁺, or Ge²⁺, A is Cs⁺, Rb⁺, CH₃NH₃_{⁺}, CH₃CH₂NH₃_{⁺}, H(C═NH₂)NH₂_{⁺}, or Me(C═NH₂)NH₂_{⁺}, X for each instance is independently F⁻, Cl⁻, Br⁻, or I⁻, and Z for each instance is independently F⁻, Cl⁻, Br⁻, or I⁻; and removing the second solvent from the uncured perovskite layer thereby forming the perovskite layer.

The first solvent, second solvent, and third solvent are not particularly limited, and the present disclosure contemplates any solvent that can at least partially solubilize and/or partially disperse the materials added to the solvent. In certain embodiments, the first solvent comprises dimethyl sulfoxide, dimethylformamide, and mixtures thereof. In certain embodiments, the second solvent comprises dimethyl sulfoxide, dimethylformamide, and mixtures thereof. In certain embodiments, the third solvent comprises water, dimethyl sulfoxide, dimethylformamide, or mixtures thereof.

In certain embodiments, the perovskite precursor solution further comprises excess PbI₂ relative to the amount of MX₂ in the precursor solution. The PbI₂ can be present in excess of 1-10 mol %, 1-9 mol %, 1-8 mol %, 1-7 mol %, 1-6 mol %, 1-5 mol %, 1-4 mol %, 1-3 mol %, 1-2 mol %, 2-10 mol %, 3-10 mol %, 4-10 mol %, 5-10 mol %, 6-10 mol %, 7-10 mol %, 8-10 mol %, 9-10 mol %, 2-9 mol %, 3-8 mol %, 4-7 mol %, 5-6 mol %, 2-6 mol %, or 3-5 mol % relative to the amount of MX₂ in the precursor solution.

Surprisingly, the electronic devices described herein exhibit improved thermal cycling, damp heat stability, and continuous light-soaking stability that result from improved mechanical, chemical and optoelectronic characteristics relative to identical electronic devices excluding the chiral compound.

In this work, we leverage the high tunability of OIHPs to facilitate chiral ammonium coordination and thereby introduce a chiral perovskite interlayer. This chiral interlayer enhances both the mechanical, chemical and optoelectronic properties of the electron-transport layer (ETL)/OIHP heterointerface in PSCs. In particular, we verified the improved durability of the ETL/OIHP interface with the chiral interlayer and resultant PSCs using the standardized International Electrotechnical Commission (IEC) 61215:2016 MQT 11 & 13 protocols and the American Society for Testing and Materials (ASTM) D3359 adhesion test.

Controlling the enantiomer components in the chiral microstructure can further enhance the mechanical properties, as exemplified by the stronger interface adhesion of racemic hetero-chiral perovskite interface (CPI) compared to homo-CPI. The racemic interface also has more favorable chemical stability and optoelectronic properties because it has a denser packing of hydrophobic benzene rings with their π-π stacking. We show that using a chiral perovskite interlayer improves device stability under standard thermal cycling, damp heat, and continuous light-soaking conditions that result from the improved mechanical, chemical and optoelectronic characteristics. The champion PCE of a device with a composition of (FAPbI₃)_{0.95}(MAPbBr₃)_{0.05} and 0.06-cm² illuminated areas based on a heterochiral interlayer reached 24.3% for n-i-p PSCs and 26.0% for p-i-n PSCs. This study serves as a proof of concept, showcasing the use of chiral chemo-mechanics to further enhance the durability of optoelectronics with layered stacks.

### Chiral Perovskite Interface Formation

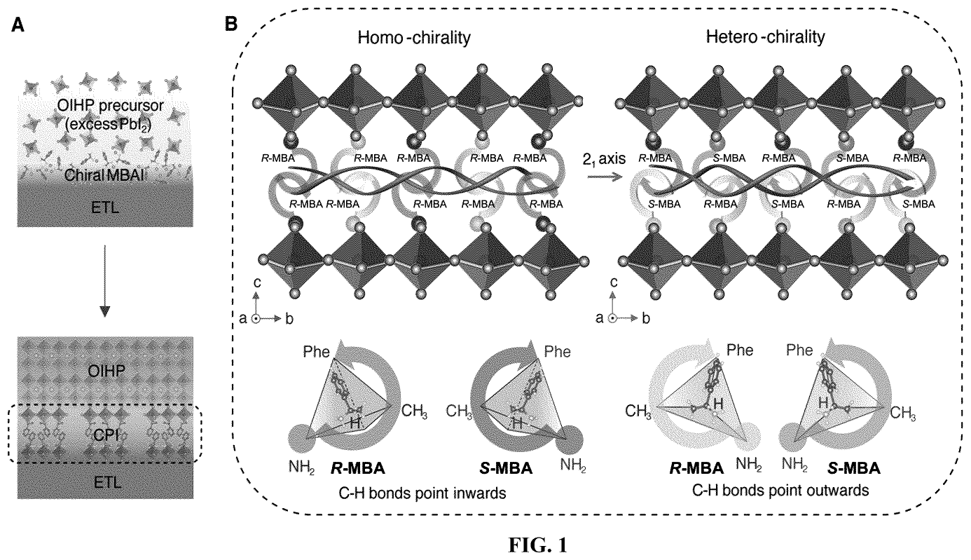

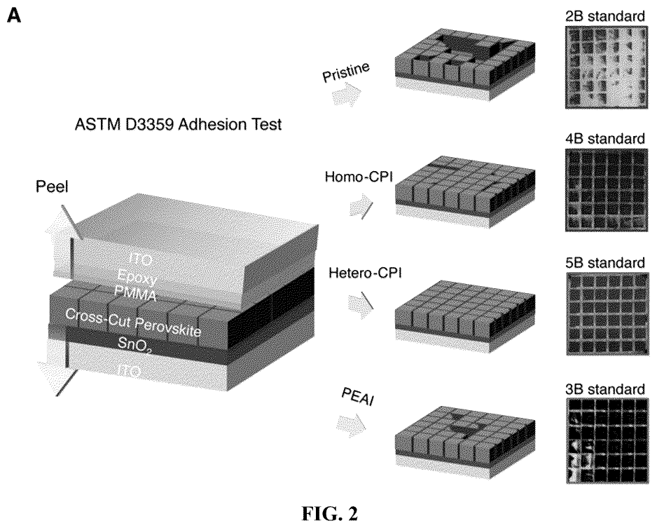

We chemically modulated the mechanical properties of chiral perovskite interlayers by using (i) a homochiral interface based solely on R-methylbenzyl-ammonium iodide (R-MBAI) or S-methylbenzyl-ammonium iodide (S-MBAI) and (ii) a heterochiral interface based on an equal mixture of R-MBAI and S-MBAI (R/S-MBAI). To form chiral-structured perovskite-substrate interlayers for conventional n-i-p structured PSCs, we deliberately incorporated chiral ammonium iodide (R- or S-MBAI) into the SnO₂ ETL, paired with excess PbI₂ in the perovskite absorber layer. For inverted p-i-n structured PSCs, we spin-coated R- or S-MBAI in an isopropanol solution atop the perovskite layer. This step was followed by an annealing-induced interdiffusion reaction that creates a chiral perovskite interfacial layer between the ETL and the perovskite layers that generates a rotational axis in the crystalline phase in the interlayer (FIG. 1A).

Ideally, this chiral interlayer should consider the following design criteria. First, the chiral molecules should form a homogeneous interface with the adjacent layers to ensure processing reproducibility. Second, the chiral molecules should contain functional groups that can produce van der Waals forces to enable adaptable binding at the interlayer. Third, the chiral interlayer should mitigate interfacial defects to facilitate charge transfer with minimized recombination. Following these considerations, we chose a pair of enantiomers, R- and S-MBAI, for developing chiral perovskite interlayers.

Taking the interlayer modulation for enhancing n-i-p PSCs' mechanical properties as an example, as schematically illustrated in FIG. 1A, the 2D homochiral and heterochiral perovskite interfaces—(R-MBA)₂PbI₄ and (R/S-MBA)₂PbI₄—form from a reaction of the excess 4% PbI₂ in the OIHP with the R-MBAI or R/S-MBAI on the ETL, respectively. Here, (R-MBA)₂PbI₄ was chosen as a typical case of a homochiral perovskite; its enantiomer compound, (S-MBA)₂PbI₄, shared an opposing configuration. We first confirmed the formation of chiral molecule enantiomers by observing the mirrored circular dichroism signals in R-MBAI and S-MBAI (centered around 257 nm), along with the silent circular dichroism signals of R/S-MBAI with the equivalent amount of R-MBAI and S-MBAI (FIG. 5).

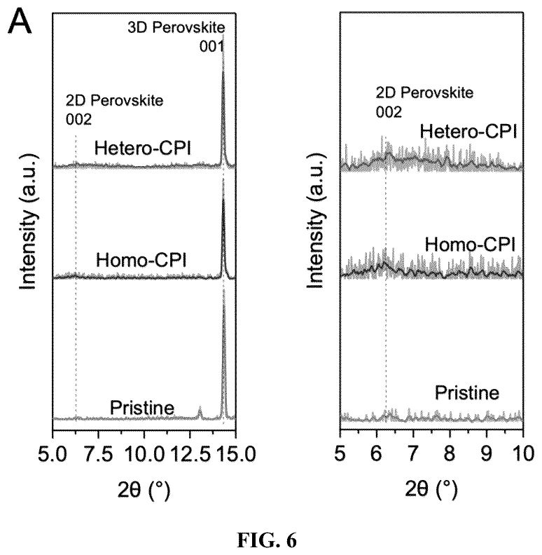

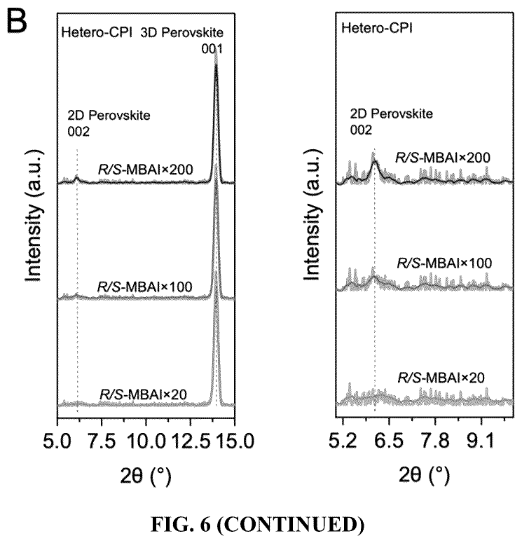

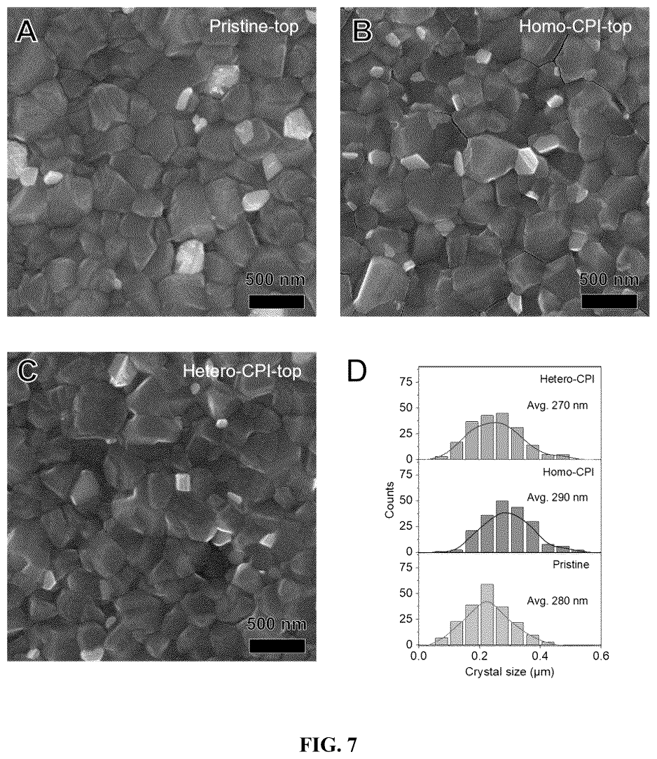

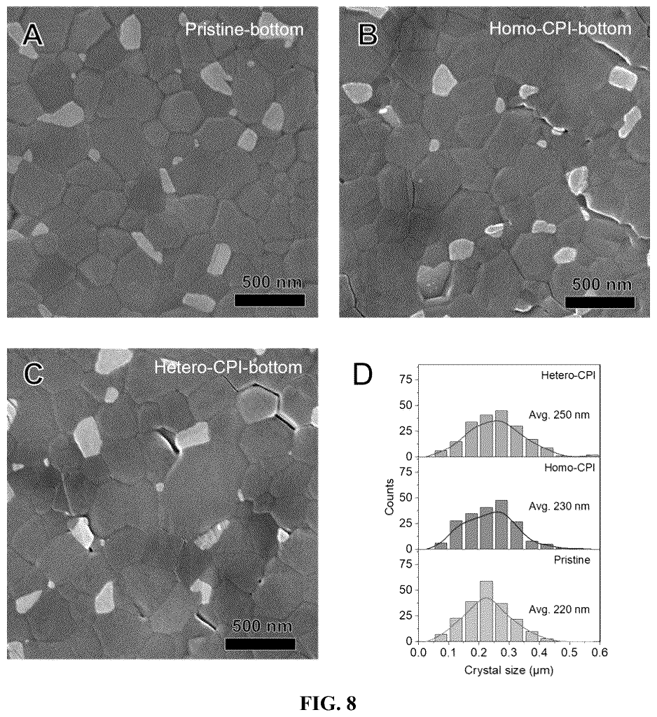

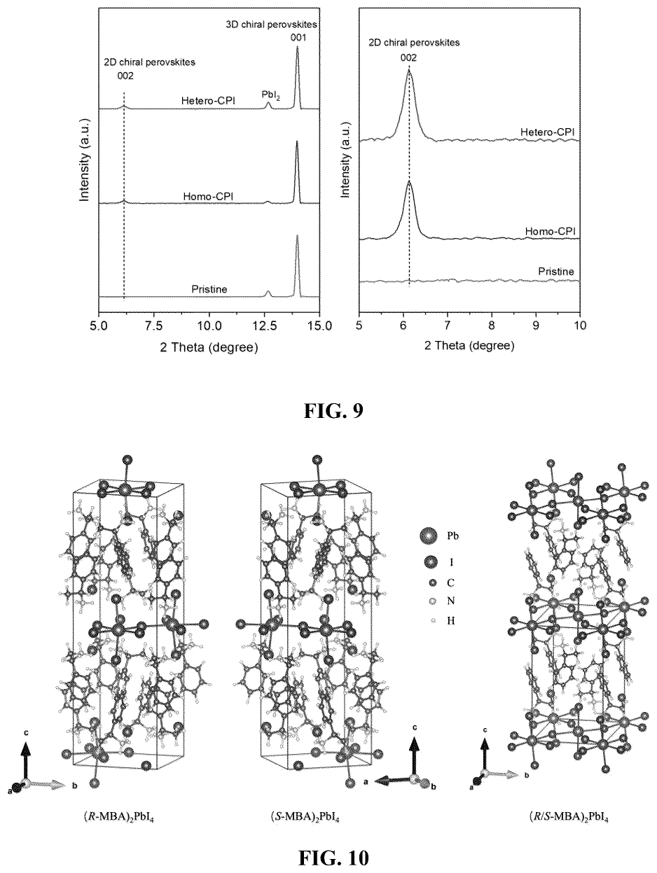

Next, we performed an X-ray diffraction (XRD) measurement on the flipped, delaminated OIHP film, which exposed the bottom surface. For both the homo- and hetero-CPI in n-i-p structured films, we observed the characteristic (002) diffraction peak at 2θ=6.10°, which should be assigned to the as-formed 2D chiral perovskite phase (FIG. 6). This peak becomes more evident when elevating the concentration of buried chiral molecules. The OIHP bottom surface maintained similar microstructures after homo- or hetero-CPI formation and showed similar morphology to that of the pristine film (FIGS. 7 and 8). These results suggest that thin CPI layers form through our fabrication route. Note that the 2D chiral perovskite layer was also observed in the surface passivation of a 3D perovskite in the p-i-n structure (glass/FTO/HTL/OIHPs/chiral molecule treatment/ETL). The homo-CPI and hetero-CPI formed on top of the 3D perovskite both showed the characteristic (002) diffraction peak of the 2D perovskite (FIG. 9).

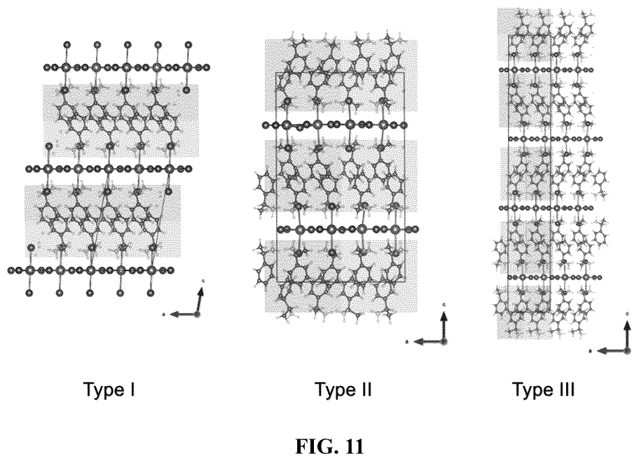

The proposed structures of the homo-CPIs are given by the corresponding single-crystal structures of (R-MBA)₂PbI₄ and (S-MBA)₂PbI₄ (FIG. 10). Although there are various possible heterochiral molecule packings in an enantiomer mixture like (R/S-MBA)₂PbI₄, the difference in binding energy among these isomers would be quite small (FIG. 11). Thus, we used a single-crystal (R/S-MBA)₂PbI₄ structure—the most stable structure—for the hetero-CPI in the following context to study the chemical and mechanical properties. As shown in FIG. 1B, the as-formed 2D chiral perovskite can be conceptualized as a combination of inorganic sheets of PbI₄²⁻ and bilayers of MBA⁺ molecules. The inorganic sheets consist of corner-sharing metal-halide octahedra. The monovalent MBA⁺ molecules form bilayers between these inorganic sheets, which are linked by the hydrogen bonds between the ammonium head of the MBA⁺ and the I⁻ ions in the axial position of the octahedra. Two MBA⁺ cations fill in the space above and below each octahedron that shares four corners in the ab crystal plane.

Because the amine enantiomers have distinct spatial configurations, the organic bilayers in homochiral and heterochiral perovskites were laid out differently between the inorganic sheet layers. In the homochiral perovskite (R-MBA)₂PbI₄ with the P2₁2₁2₁ space group, the arrangement of the two R-MBA⁺ bilayers between inorganic sheets are rotational along the a-, b-, and c-axis, resulting in helical stacking with the 2₁ helical axis in three directions. In contrast, because of the geometry difference of the enantiomer, the heterochiral bilayers of R-MBA⁺ and S-MBA⁺ in (R/S-MBA)₂PbI₄ with P2₁/a space group are only rotationally arranged along the b-axis, with the 2₁ rotation symmetry along this axis. Meanwhile, in the b-axis direction of the chiral perovskite, (R-MBA)₂PbI₄ only has helix packing generated by right-handed molecules (red color helical strips in FIG. 1B), whereas (R/S-MBA)₂PbI₄ has both left- and right-handed molecule helical packing (blue and red color helical strips in FIG. 1B). These two helical packing strips are bonded by π-π stacking of the benzene rings from the same and opposing configurations for (R-MBA)₂PbI₄ and (R/S-MBA)₂PbI₄, respectively.

### Interfacial Mechanical Properties

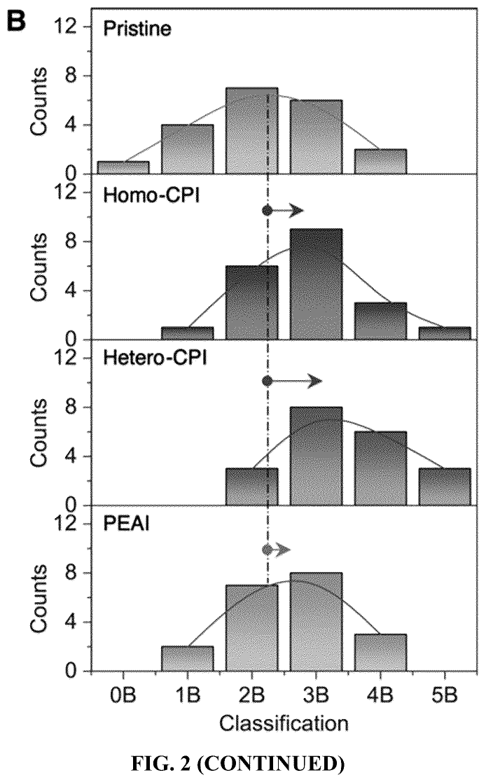

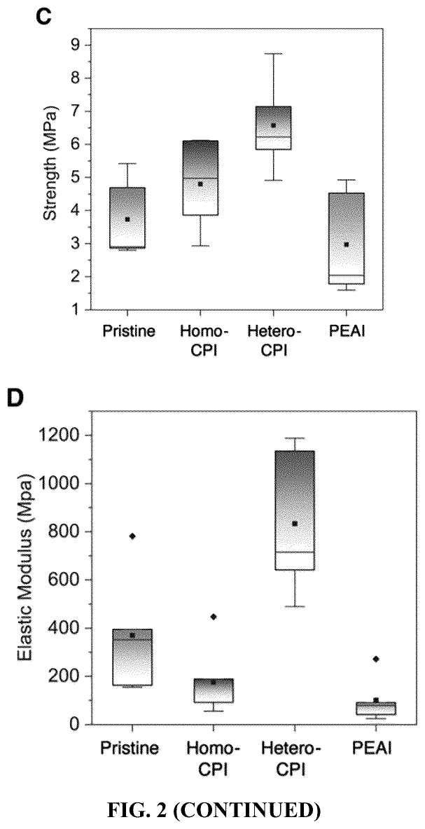

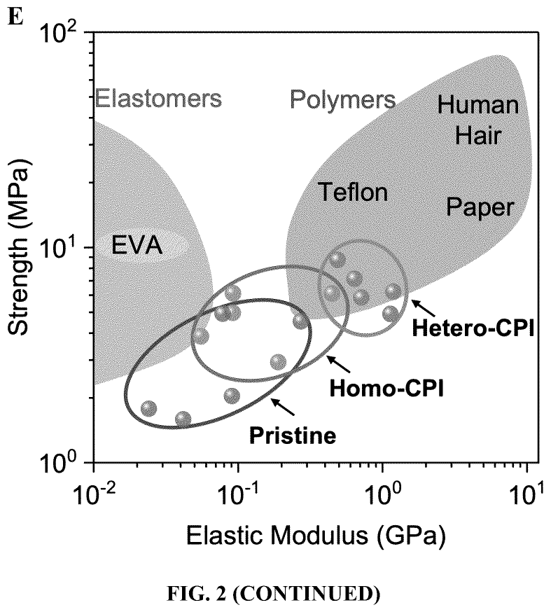

We studied the mechanical properties of the chiral-structured interlayer based on the SnO₂/OIHP interface that is typically adopted for n-i-p structured PSCs. The delamination resistance of OIHPs was evaluated according to the film adhesion test. As depicted in FIG. 2A, the samples for mechanical tests were prepared as symmetrical sandwich structures. First, a thin layer of polymethyl methacrylate was spin-coated on OIHPs to protect the perovskite from chemical corrosion and surface strain from the epoxy glue. Next, a multi-blade tool with seven edges spaced 1 mm apart was used to crosscut the OIHP coating and penetrate the substrate. An epoxy resin was coated on the carved OIHP and covered by a piece of indium tin oxide (ITO) glass on the sample, which was placed in a glove box at room temperature for more than 24 hours to cure the polymer. Finally, the top-covered ITO was peeled off to leave the strongly adhered part of the OIHP on the substrate. Generally, we observed that OIHPs with homo- and hetero-CPIs have more intact areas (squares, as illustrated in FIG. 2A) than pristine structures. We also assessed the mechanical reliability of homo- and hetero-CPI in comparison to a nonchiral OIHP/ETL interface created using phenethylammonium iodide (PEAI), a prevalent achiral interface passivation molecule and an isomer of MBAI (C₈H₁₂IN). Although the PEAI-based interlayer also improved the adhesion between OIHP and ETL, it was not as effective as the homo- and hetero-CPIs.

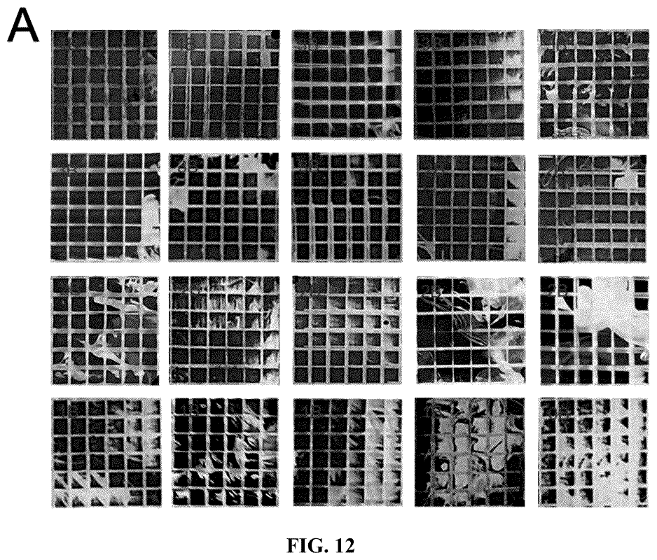

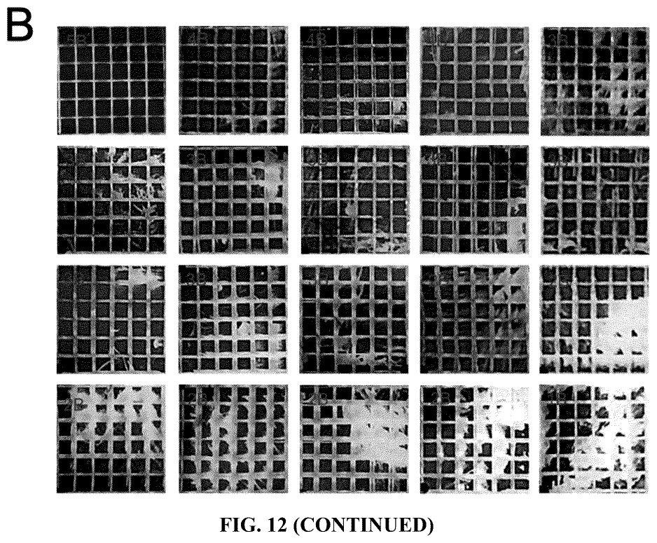

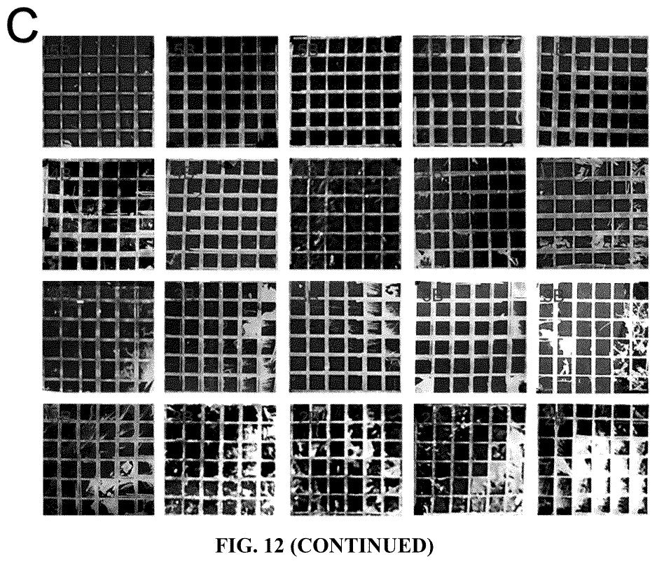

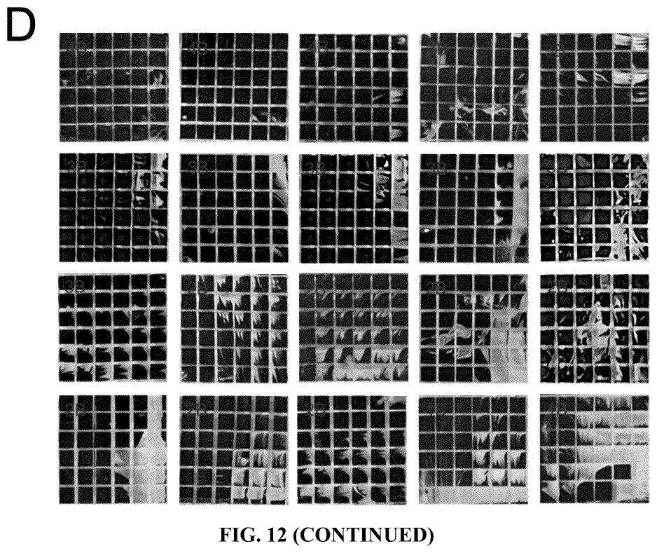

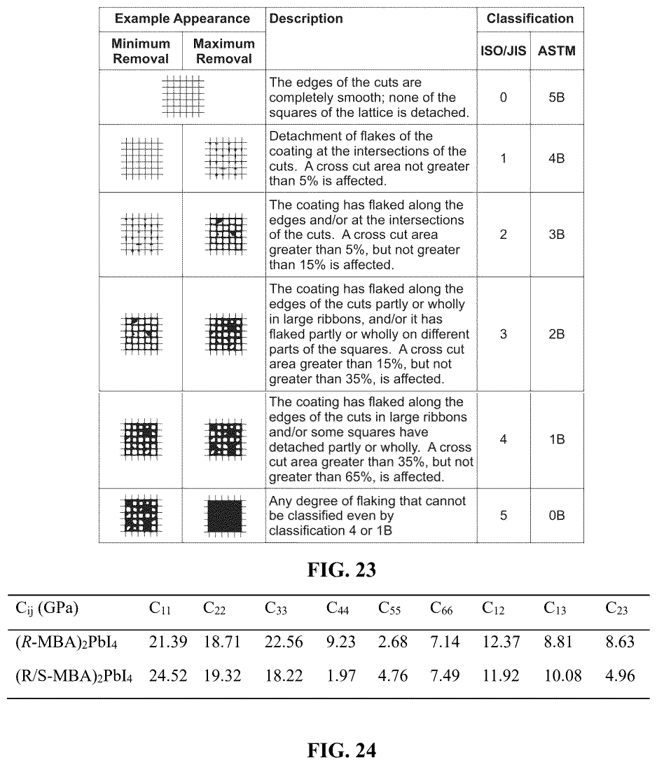

To acquire the statistical evidence for the enhanced mechanical reliability of these interfaces, we assessed the 20 crosscut areas of OIHPs for each of the four samples (pristine SnO₂, homo-CPI, hetero-CPI, and PEAI) through ASTM D3359 adhesion classification (FIG. 2B, and FIG. 12). The adhesion-delamination classification was determined by the retained parts of the crosscut area, which displayed enhanced adhesion from 0B to 5B in accordance with the standard (FIG. 23, Table 1). Specifically, the OIHP adhesion on pristine SnO₂ was classified as 2B, corresponding to an area >15% but <35% of the area affected across the grid, whereas the homo-CPI and hetero-CPI cases were classified as 3B, corresponding to >5% but <15% of the area affected across the grid. Compared with homo-CPI, OIHPs with hetero-CPI had an overall higher degree of adhesion. Moreover, only homo- and hetero-CPI samples exhibited 5B grade adhesion results, accounting for 5% and 15% of the respective samples, corresponding to none of the squares affected. OIHPs adhesion on the control PEAI-modified interface is classified between 2B and 3B, indicating relatively less significant improvement. These results underscored the value of using chiral geometry to improve mechanical adhesion.

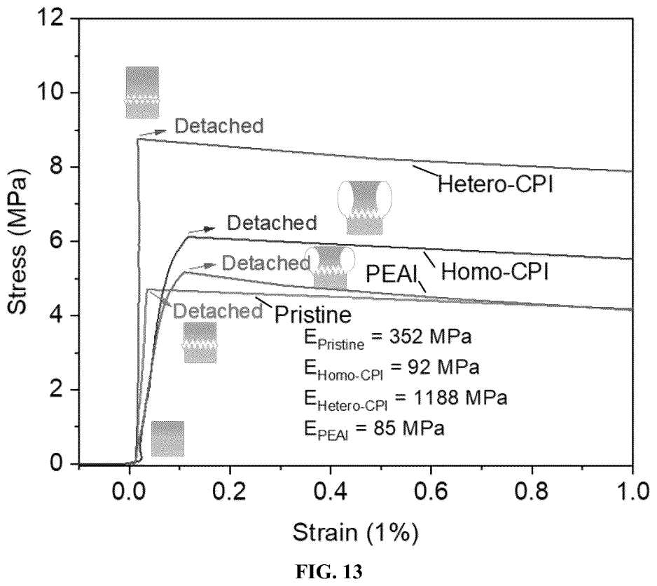

We further studied the mechanical properties of the ETL/OIHP interface using uniaxial tensile testing (12). The specimen's structure was similar to that used for the adhesion tests, except for a generated tiny notch by blade at the ETL/OIHP interface to guide the fracture at the interface. The strain-stress curves show that the strength (maximum detachment stress) of pristine ETL/OIHP (σ_{Pristine}=4.70 MPa) is smaller than that for the homo-CPI (σ_{Homo-CPI}=6.12 MPa) and hetero-CPI (σ_{Hetero-CPI}=8.76 MPa) cases, but comparable to the PEAI-modified interface (σ_{PEAI}=5.17 MPa) (FIG. 13). This result is consistent with the results in FIG. 2B from the alternative delamination test. Based on the experiments, the hetero-CPI exhibits the highest elastic modulus (Young's modulus, E_{Hetero-CPI}=1182 MPa), followed by pristine SnO₂ (E_{Pristine}=352 MPa), homo-CPI (E_{Homo-CPI}=92 MPa), and PEAI (E_{PEAI}=85 MPa). These results are derived from the linear slopes of the elastic deformation region. The hetero-CPI and pristine interfaces undergo elastic deformation throughout the tensile process, whereas irreversible plastic deformation, corresponding to the start of the nonlinear response region after the applied strain, is seen for both the homo-CPI and PEAI interfaces.

To obtain a more comprehensive understanding of the interfacial mechanical properties of these three materials, we investigated five samples of each for interfacial fracture strength and elastic modulus. The mean strength of the pristine ETL/OIHP interface was enhanced by 28% and 76% for the homo-CPI and hetero-CPI, respectively, but that was reduced by 20% for the PEAI interface (FIG. 2C). The mechanical strength of the interface was enhanced through the formation of (R-MBA)₂PbI₄ and (R/S-MBA)₂PbI₄ 2D perovskite. The elastic modulus decreased by 53% and 71% for the homo-CPI and PEAI interfaces, respectively, but increased by 125% for hetero-CPI (FIG. 2D). Here, we consider that homo-CPI acts like a molecular spring, enhancing interface elasticity, but it is more susceptible to elastic deformation, resulting in a smaller Young's modulus. In contrast, hetero-CPI, formed by connecting enantiomers with opposite chirality through 7 bonds, exhibits an improved Young's modulus while maintaining excellent elastic deformation recovery capability. Consequently, hetero-CPI reduces the elastic deformation displacement under the same stress compared to homo-CPI.

We attributed the large discrepancy in the elastic modulus among the three interlayers to the packing difference of organic ammonium in 2D perovskite. In the elastic modulus-strength map (FIG. 2E), the mechanical property of the homo-CPI was analogous to an elastomer, whereas hetero-CPI was more like a polymer. These results also implied that the racemic hetero-CPI had the highest strength and elastic modulus, as well as optimum mechanical properties. For analogy, among natural polymers, chiral polymers also demonstrate excellent strength and Young's modulus, as seen in materials like cellulose-based paper and keratin-based hair.

We also investigated the influence of the homo- and hetero-CPIs on the various mechanical properties. (R-MBA)₂PbI₄ and (R/S-MBA)₂PbI₄ theoretically exhibited distinct elastic constants (FIG. 24, Table 2). As mentioned above, the (001) plane is the preferred growth plane for (R-MBA)₂PbI₄ and (R/S-MBA)₂PbI₄. For the layered (R-MBA)₂PbI₄ and (R/S-MBA)₂PbI₄, the strong in-plane interaction induces large in-plane elastic constants (C₁₁ and C₂₂) and small C₃₃ that results from the weak interlayer interaction. Because the (R-MBA)₂PbI₄ and (R/S-MBA)₂PbI₄ layers are relatively thin compared to the SnO₂ and perovskite layers, we only analysed the elastic constants based on the dominating contact crystal plane. (R/S-MBA)₂PbI₄ shows more favourable in-plane mechanical properties than (R-MBA)₂PbI₄ in that it had larger C₁₁ and C₂₂ values. Moreover, the larger elastic constant C₅₅ of (R/S-MBA)₂PbI₄ indicates stronger resistance to shear force along the c-axis on the a-plane. Thus, incorporating a thin (R/S-MBA)₂PbI₄ layer as an interlayer leads to a higher elastic modulus.

### Photoluminescence Studies

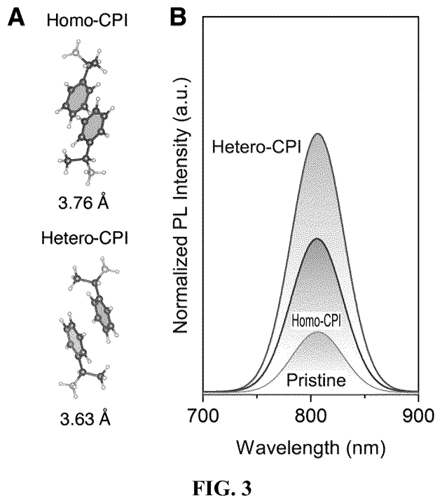

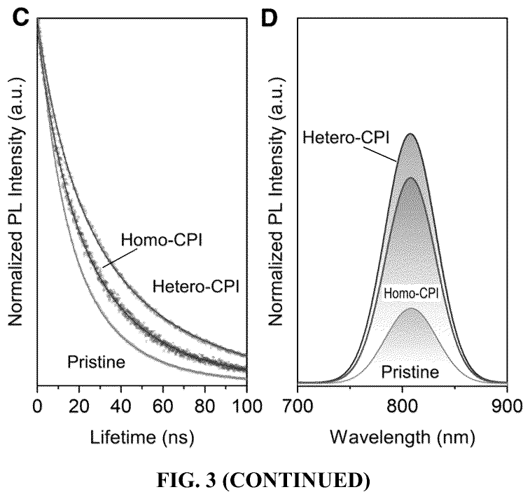

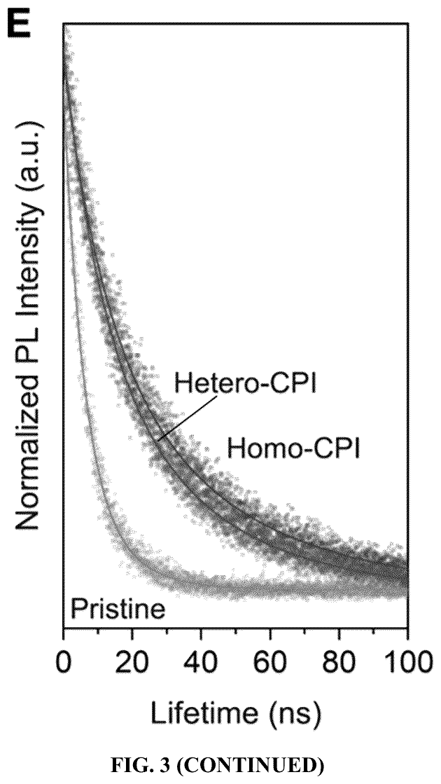

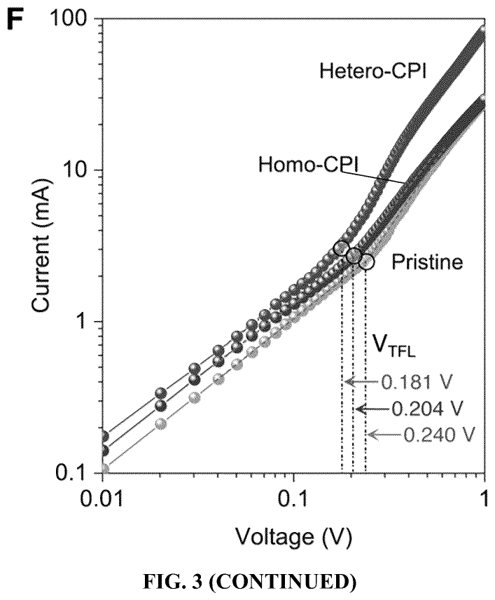

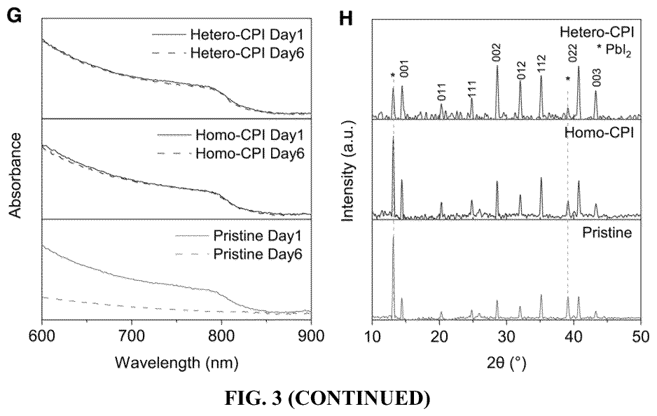

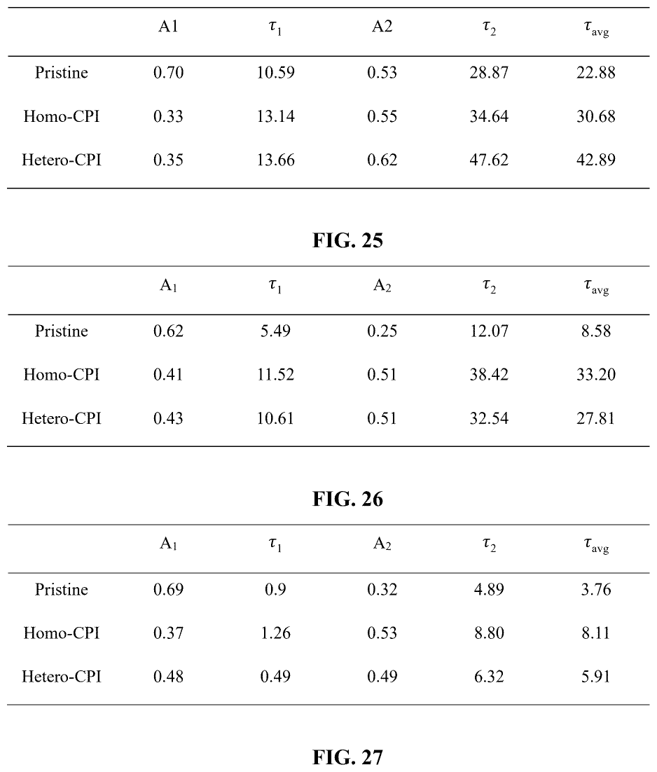

We used photoluminescence (PL) and time-resolved photoluminescence (TRPL) to investigate the impact of different MBA⁺ stacking patterns (FIG. 3A) on charge carrier dynamics across the ETL/OIHP interface. We first studied the intrinsic PL properties of the perovskite layers. The samples were prepared by delaminating them from the substrates as for the adhesion tests. The PL and TRPL spectra in FIGS. 3B and C were obtained by 375 nm laser excitation from the air side. The fitted biexponential decay lifetimes for an OIHP film with different interfaces are shown in FIG. 25, Table 3. We found that the PL intensities for hetero- and homo-CPI cases increase by 317% and 149%, respectively, compared to that for the pristine case (FIG. 3B). The enhancements of the PL intensity for homo-CPI and hetero-CPI are consistent with the passivation of traps, which can reduce the nonradiative recombination from the Shockley-Read-Hall process. We measured TRPL with a pulse fluence of approximately 14.15 μJ/cm². The passivation at the OIHP/ETL interface by the CPIs contributes to long PL lifetimes—30.8 ns for homo-CPI and 42.9 ns for hetero-CPI, compared to 22.9 ns for pristine (FIG. 3C).

The PL and TRPL spectra in FIGS. 3D and E were obtained by 375 nm laser excitation from the glass side around the ETL/OIHP interface. FIG. 26, Table 4 shows the fitted biexponential decay lifetimes for an OIHP film with different interfaces are shown. The PL spectra in FIG. 3D also demonstrate enhanced radiative emission of the photogenerated free carriers for the CPI-incorporated SnO₂/OIHP, likely from the formation of ultrathin 2D perovskite. This 2D motif has been shown to be effective at controlling defects at the OIHP interface. Compared to pristine SnO₂/OIHP, homo- and hetero-CPIs exhibit steady-state PL intensity increases of 228% and 170%, respectively. In addition, the PL peak position shows a slight blue shift from 808.5 nm for the pristine sample to 807.6 nm and 807.9 nm for the homo-CPI and hetero-CPI samples, respectively, which could be attributed to chiral MBAI passivating the shallow trap states near the bottom surface.

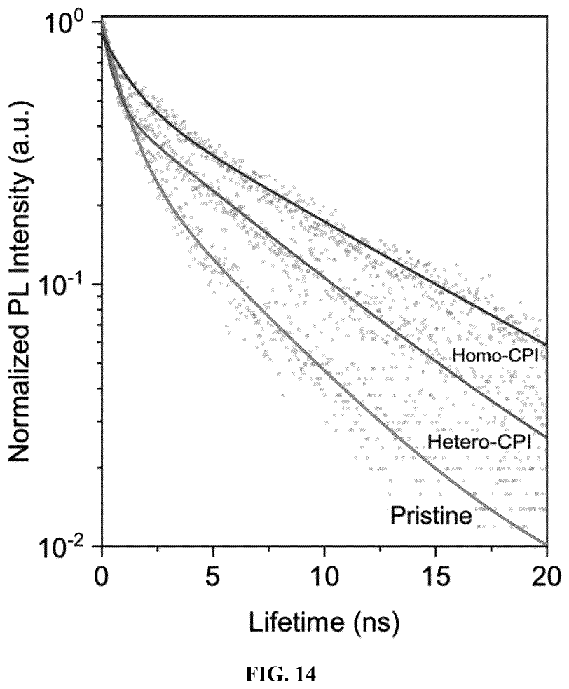

In general, the fast component of decay lifetime (τ₁) is assigned to monomolecular charge trapping into nonradiative trap states, and the slow component (τ₂) is assigned to bimolecular recombination. As shown in FIG. 3E, the decay lifetime of this fast compound among films is 5.49, 11.52, and 10.61 ns for pristine SnO₂, homo-CPI, and hetero-CPI, respectively. These results indicate that the density of nonradiative trap states is the highest in the pristine SnO₂/OIHP film and relatively lower in homo- and hetero-CPI/OIHP films, consistent with the steady-state spectroscopic data discussed above. Furthermore, we assessed the carrier transport dynamic of ETL/CPI on the surface of OIHP (FIG. 14). The inclusion of C₆₀ ETL at the top OIHP results in the acceleration of fast component PL decays with 0.90, 1.26, and 0.49 ns for the pristine OIHP surface, homo-CPI, and hetero-CPI, respectively, indicating charge transfer to these CTLs (FIG. 14 and FIG. 27, Table 5). For the hetero-CPI, even greater facilitated carrier injection is seen, for which we attributed to the closer packing of benzene rings compared to that in the homo-CPI.

To further examine the effect of a chiral ETL/OIHP interface on the trap density of OIHP films, we fabricated capacitor-like devices sandwiching the OIHP films between ITO/SnO₂ and PCBM/Ag and studied them using space-charge-limited current measurements at varying biases (FIG. 3F). The estimated electron trap densities for OIHP films on homo-CPI and hetero-CPI decreased by 17% and 25%, respectively, in comparison to the pristine case. The decreased trap densities in the OIHP film with the chiral-structured interfaces are attributed to the passivation of interfacial defects for effective electron transport.

### Chemical Stability

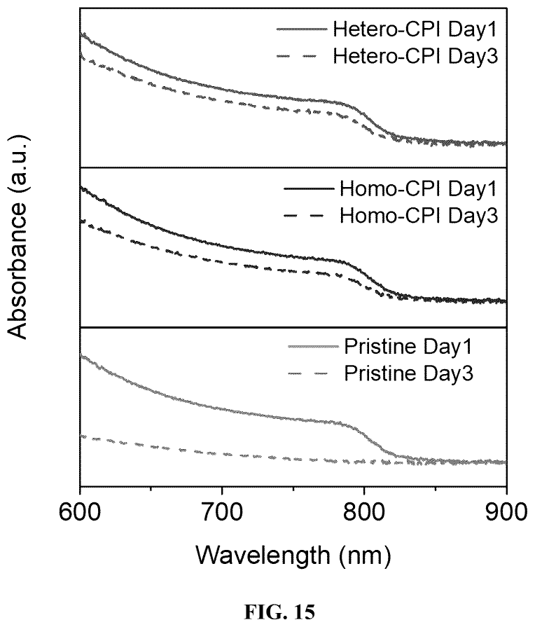

As shown in FIG. 3G, the chemical stability of the three ETL/OIHPs was assessed by tracking the evolution of the ultraviolet-visible (UV-vis) absorption while the devices were stored under ambient conditions (room temperature and 65% RH). The absorption of the OIHP thin film on pristine SnO₂ decreases rapidly, and the film completely degrades in 6 days under 65% RH. The initial absorption is nearly unchanged for the OIHPs on homo- and hetero-CPIs. The degradation of the OIHP to PbI₂ is revealed by XRD for the buried interfaces, prepared through the adhesion test (FIG. 3H). Based on the change in the diffraction peak integrated intensity ratio—(001) for PbI₂ to (001) for OIHP—we observed that degradation is substantially slower in the homo-CPI (I_{PbI2/OIHP}˜2.04) and hetero-CPI (I_{PbI2/OIHP}˜0.88) samples compared to the pristine SnO₂ case (I_{PbI2/OIHP}˜3.60). Similarly, the thermal tolerance of OIHPs on various ETLs was evaluated under the ambient heating process (100° C. and 20% RH). The absorption of OIHP thin film on pristine SnO₂ decreases rapidly within 3 days in a dry box with 20% RH, compared to perovskite on a chiral additive ETL (FIG. 15).

### Solar Cell Fabrication and Testing

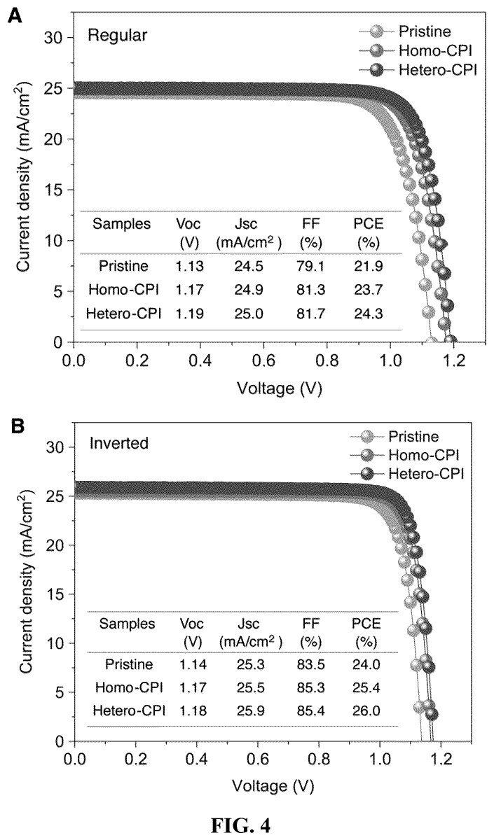

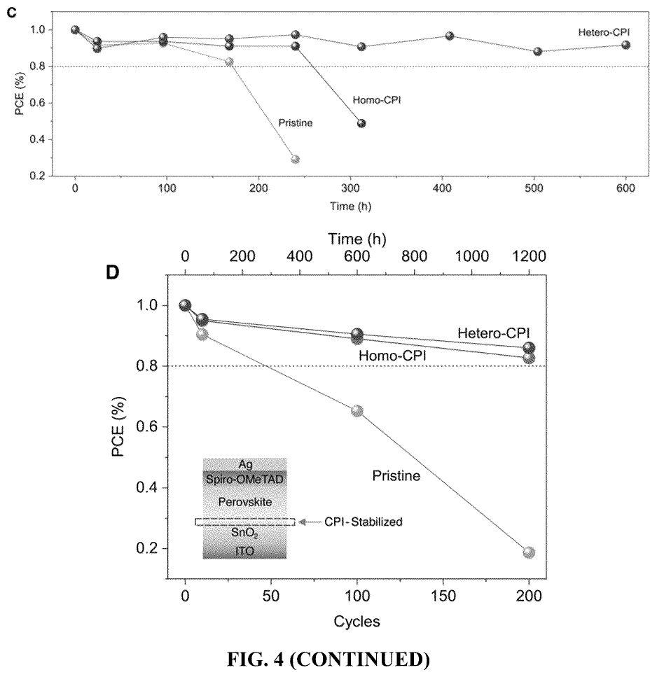

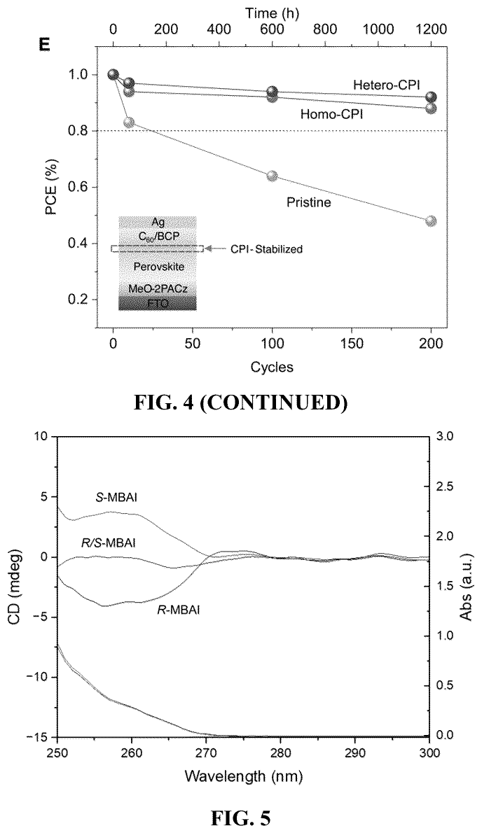

We fabricated PSC devices based on both n-i-p and p-i-n structures to assess the photovoltaic performance. FIG. 4A shows the current density-voltage (J-V) curves of n-i-p PSC devices based on pristine SnO₂, homo-CPI, and hetero-CPI at reverse scans under stimulated air mass 1.5 -G one-sun illumination for an active area of 0.06 cm². The heterochiral interlayer engineering enhances the efficiency of the devices, as seen by a champion PCE of 24.3%, a short-circuit current density (J_{SC}) of 25.0 mA cm-2, an open-circuit voltage (V_{OC}) of 1.19 V, and a fill factor (FF) of 0.817. In comparison, the PSCs with pristine SnO₂ and homo-CPI exhibit a PCE of 21.9% and 23.7%, a V_{OC} of 1.13 V and 1.17 V, an FF of 0.791 and 0.813, and a J_{SC} of 24.5 mA cm² and 24.9 mA cm², respectively.

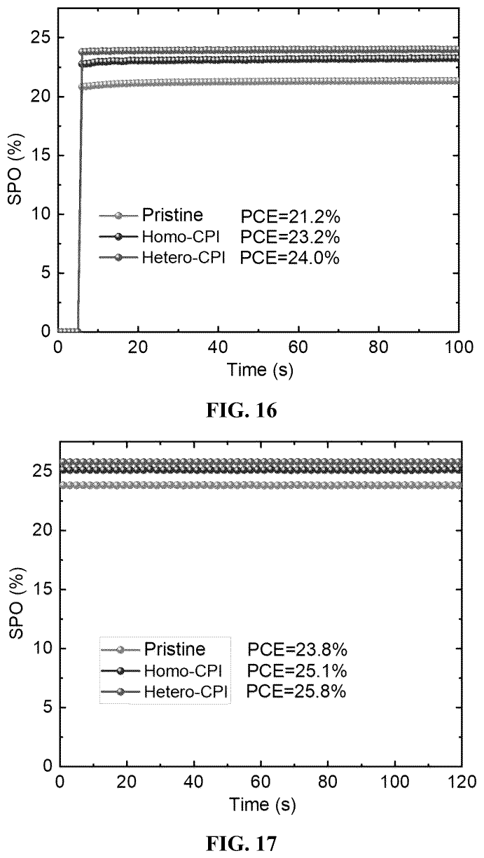

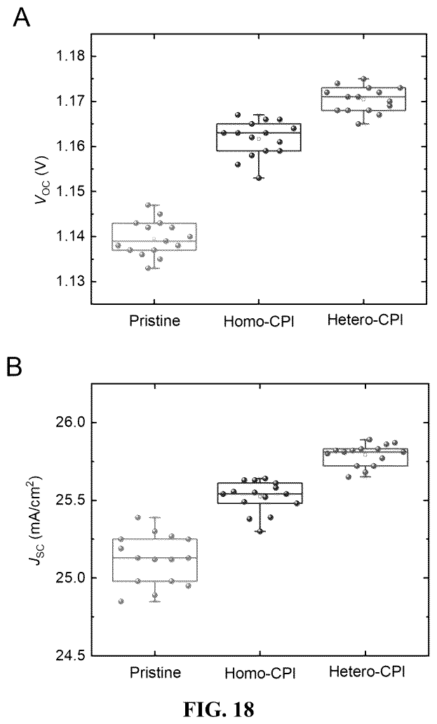

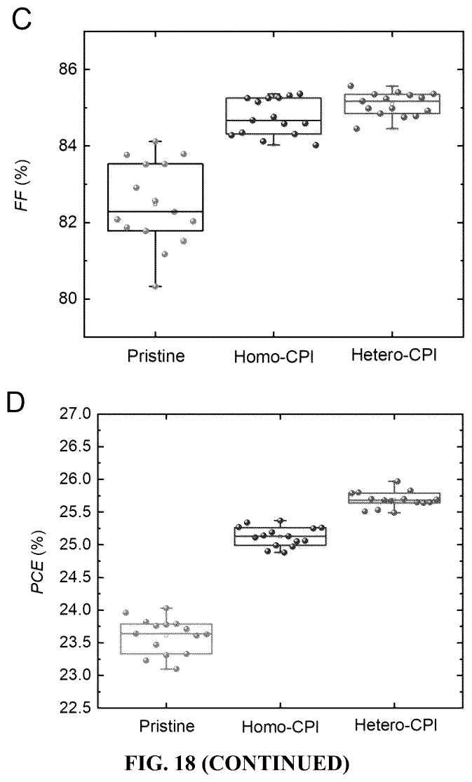

As shown in FIG. 16, the stabilizing power outputs (SPO) of the devices were monitored at the maximum power point for 100 s. Stabilized PCE values for devices with pristine SnO₂ and homo- and hetero-CPI were 21.2%, 23.2%, and 24.0%, respectively. FIG. 4B shows the J-V curves of p-i-n PSC devices based on the CPI between the HTL and OIHP. In reverse scans, the hetero-CPI engineering yields a champion PCE of 26.0%, a J_{SC} of 25.9 mA cm⁻², a V_{OC} of 1.18 V, and an FF of 85.4%. P-i-n PSCs with pristine SnO₂ and homo-CPI show a PCE of 24.0% and 25.4%, a V_{OC} of 1.14 V and 1.17 V, an FF of 83.5% and 85.3%, and a J_{SC} of 25.3 mA cm² and 25.5 mA cm², respectively. The SPO of the p-i-n devices with pristine SnO₂ and homo- and hetero-CPI are 23.8%, 25.1%, and 25.8%, respectively (FIG. 17). FIG. 18 shows the p-i-n devices' parameters statistics including V_{OC}, J_{SC}, FF, and PCE, of 15 individual PSCs based on pristine, homo-CPI and hetero-CPI, indicating good device reproducibility.

### Stability Testing

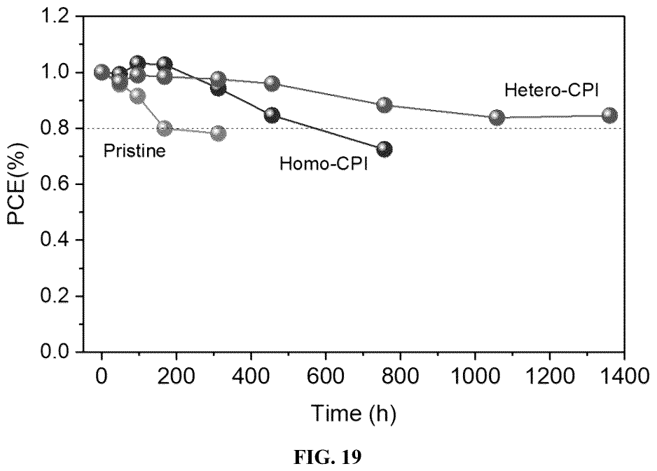

The R/S-MBAI-engineered PSCs exhibited enhanced stability under a variety of test conditions. We initially monitored the PCE evolution under light-soaking, with the light intensity equivalent to 1 Sun (100 mW cm⁻²). After 1360 hours, the unencapsulated PSC with hetero-CPI retains 84% PCE, indicating light stability enhancement (FIG. 19). Hetero-CPI also exhibits excellent antifatigue properties under damp heat conditions, according to the IEC 61215:2016 test standard, MQT 13 (FIG. 4C). The PSCs are all encapsulated using UV-curing adhesive with a cover glass. Then, the edge of the cover glass was further protected by epoxy and cured at room temperature for more than 48 hours. The glass-encapsulated device maintains 92% of its original performance after being exposed to an 85% humid environment at 85° C. for 600 hours.

We also studied the thermal cycling test conditions between −40° C. and 85° C. using the IEC 61215:2016 MQT 11 protocol. In the conditions of thermal cycling, n-i-p PSCs based on homo- and hetero-CPIs, both preserve >80% of their original performance after 200 cycles. However, the PCE of the pristine ETL drops rapidly to 61% after 100 temperature cycles (FIG. 4D). Homo- and hetero-CPIs in p-i-n PSCs manifest better retention of PCE, retaining >88% after 200 cycles. For comparison, the PCE of the PSC with a pristine ETL drops rapidly to 64% after 100 temperature cycles (FIG. 4E).

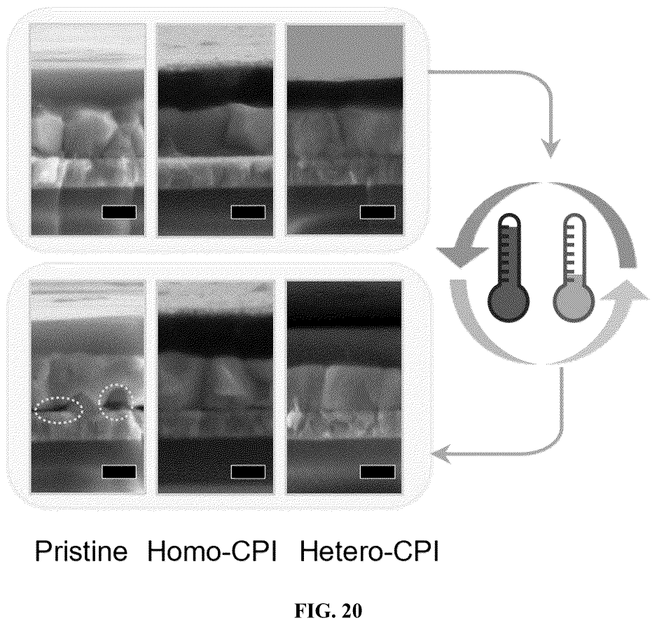

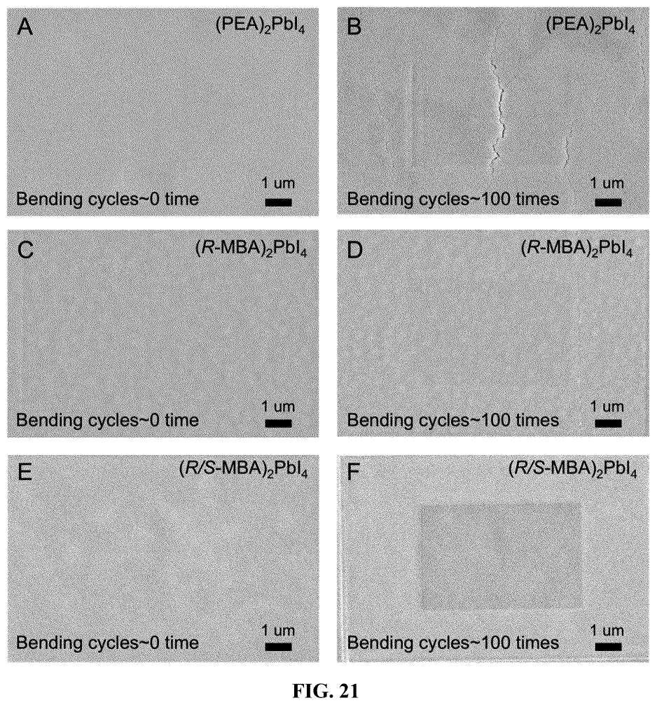

In both PSC architectures, the hetero-CPI shows outstanding durability, with 86% and 92% of the original PCE preserved for n-i-p and p-i-n structures, respectively. As shown in the insets of FIG. 20, the pristine ETL/OIHP interface shows obvious delamination and pinholes after thermal cycling tests that is the result of its deficiency in interfacial mechanical properties. Homo- and hetero-CPI cases, in contrast, do not exhibit any obvious interfacial defects after being subjected to this same thermal cycling test. These results again demonstrate the benefits of the OIHP with CPI produces high mechanical integrity and tolerance. We further investigated the bending mechanical property of (PEA)₂PbI₄, (R-MBA)₂PbI₄, and (R/S-MBA)₂PbI₄ films on PEN/ITO substrate (FIG. 21). (R/S-MBA)₂PbI₄ and (R-MBA)₂PbI₄ films show strong resistance to crack generation after 100 times bending cycle, compared to (PEA)₂PbI₄ with obvious crack formation. This result implies that the chiral interface modulates ETL/OIHP and could resemble mechanical springiness with a larger toughness over the nonchiral interface.

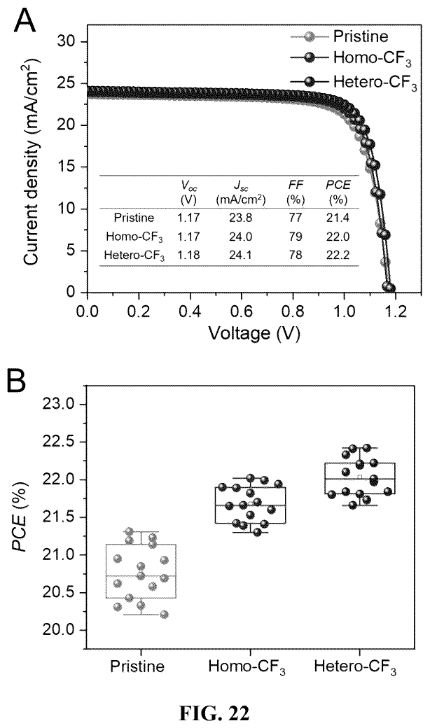

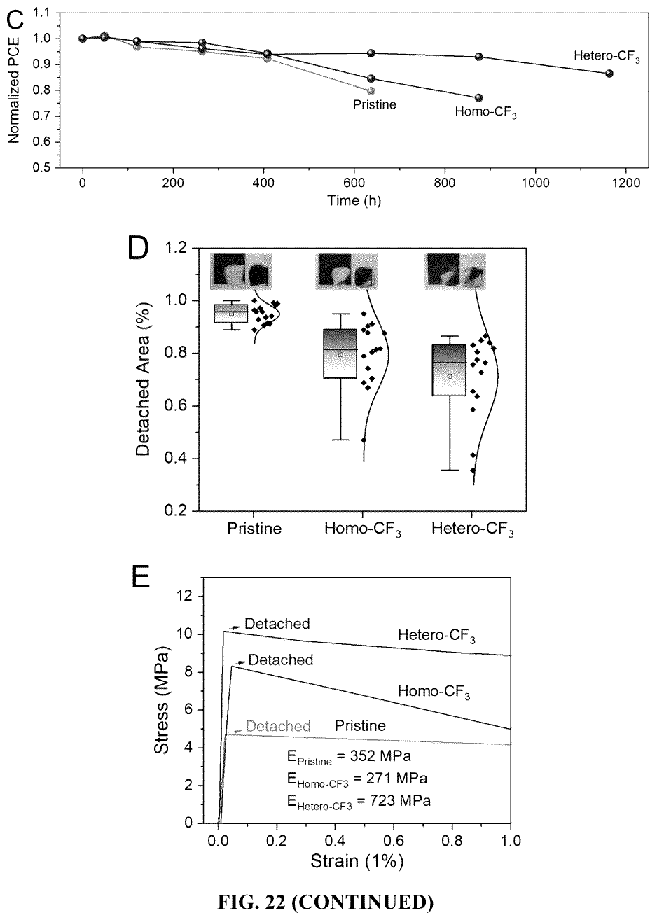

As mentioned above, the role of chiral molecule enantiomers influences the molecular packing configurations within the heterointerface, affecting intermolecular interactions and structural stability. We have also tested other categories of R or S ammonium molecules, R-2-amino-1,1,1-trifluoropropane hydrochloride (R—CF₃) and S-2-amino-1,1,1-trifluoropropane hydrochloride (S—CF₃). Using this pair of chiral molecules, we also fabricated homo-chiral (homo-CF₃) or hetero-chiral (hetero-CF₃) interfaces between the OIHP and ETL in n-i-p structured PSCs. Based on the results of PV performance, stability, and mechanical properties, the PSCs based on hetero-CF₃ and homo-CF₃ consistently show advantages over pristine SnO₂, and the hetero-CF₃ shows a higher level of enhancement (FIG. 22). These results are consistent with the MBAI-based chiral interface modification, demonstrating the generality of the CPI approach.

We have shown that chiral-structured perovskite interlayers with dynamically durable chiral packing enhance the mechanical, chemical, and carrier-extracting properties of the ETL/OIHP heterointerface. Highly efficient PSCs with chiral perovskite interlayers demonstrate promising tolerance to thermal cycling, damp heat, and light-soaking conditions. Furthermore, a heterochiral interlayer with a racemic mixture of right- and left-handedness shows additional enhancements, which harness the merits of the higher packing density of organic molecules, higher mixing entropy, and higher elastic modulus. The enhanced moisture stability for PSCs with hetero-CPI also benefits from strong in-plane binding and close hydrophobic benzene ring packing, thus preventing moisture from penetrating the interlayer between OIHP and ETL. These heterochiral findings have the potential to play a pivotal role in translating cell-level considerations to module-level stability assessments, marking a natural progression beyond existing research in this field. Our work presents a proof of principle for designing stable and efficient heterointerfaces by utilizing chiral perovskite interlayers with tailored chemical/physical/mechanical properties to further advance PSCs and other optoelectronic applications.

### EXAMPLES

### Materials and Methods

### Chemicals

PbBr₂ (≥99%), HI (57 wt. % in H₂O), Diethyl ether (≥99%), 4-tert-butylpyridine (TBP, 96%), Bis (trifluoromethane) sulfonamide lithium salt (99.95%), and dimethylformamide (DMF, 99.8%), dimethyl sulfoxide (DMSO, 99.9%), chlorobenzene (CB, 99.8%) and diethyl ether (DEE, 99.0%) were acquired from Sigma-Aldrich (USA). (R)-(+)-α-methylbenzylamine (>99%) and (S)-(−)-α-methylbenzylamine (>99%), [2-(3,6-dimethoxy-9h-carbazol-9-yl)ethyl]phosphonic acid (MeO-2PACz, >99%), bathocuproine (BCP, >99%) and PbI₂ (>99%) were acquired from TCI (Japan). formamidinium bromide (FABr, >99.99%), formamidinium iodide (FAI, >99.99%), methylammonium chloride (MACl, >99.99%), methylammonium iodide (MAI, >99.99%), phenethylammonium iodide (PEAI, >99.99%), and n-octylammonium iodide (OAI, >99%) were purchased from Greatcell Solar (Australia). Tin(IV) oxide (15 wt. % in H₂O colloidal dispersion) and CsI (99.998%) were acquired from Alfa Aesar (USA). Spiro-OMeTAD (99.8%) was purchased from Borun Chemical Co., Ltd. (China). C₆₀ was purchased from Lumtec. All raw chemicals were used as received without further purification.

### Example 1—Preparation of Chiral Ammonium Iodide

Take the synthesis of R-MBAI as an example, 1.1 g (R)-(+)-α-methylbenzylamine and 1.16 g HI (57 wt. % in H₂O) were added in a flask at 0° C. (ice bath) with stirring and under nitrogen protection, the reaction was carried out for 2 hours. Then, water was removed by rotary evaporation at 80° C. for 2 hours. The resulting solution was washed with diethyl ether until it became colourless, and the product was collected. Finally, the product was filtered and dried in a vacuum oven for about 12 hours. A similar procedure was also applied to synthesize S-MBAI. The R/S-MBAI is the racemic mixture of an equivalent amount of R-MBAI and S-MBAI.

### Example 2—Preparation of Perovskite Thin Films for Mechanical, Optical and Stability Properties Study

FA_{0.9}Cs_{0.1}PbI₃ precursor solution (1M) for thin film fabrication typically contains mixed powder of FAI (154.8 mg), CsI (26.0 mg) and PbI₂ (461.1 mg) in 1 mL solvent (700 μL DMF and 300 μL DMSO), and was stirred at room temperature for 2 h before use. To prepare the FA_{0.9}Cs_{0.1}PbI₃ (4% excess PbI₂) perovskite precursor, an additional 18.4 mg PbI₂ was added into the above perovskite precursor. SnO₂ electron-transport layer (ETL) on indium tin oxide (ITO) glass was first synthesized using dilute commercial SnO₂ nanoparticle solution (VH₂O: VSnO₂=5.25:1). Chiral perovskite interface (CPI) was fabricated through a modified procedure by adding 5 mg R- or R/S-MBAI in 1 mL dilute SnO₂ nanoparticle solution. This protocol was also applied for the synthesis of the PEAI interface. Then, the ETL precursor was spin-coated on glass/ITO substrates in ambient air at 3000 rpm for 30 s, and annealed at 180° C. for 30 min. FA_{0.9}Cs_{0.1}PbI₃ perovskite layer was formed using 50 μL above precursor spreading on the ETL substrate, followed by a three-stage spin-coating process (500 rpm for 5 s, 1000 rpm for 10 s and 5000 rpm for 30 s). During the third stage, 200 μL of CB was dripped on the spinning substrate, followed by annealing at 170° C. for 5 min.

### Example 3—Material Characterization and Property Measurement

CD spectra and related absorption spectra were measured using BioLogic CD (MOS 500) with a scan speed of 2 nm/s from 250-300 nm. XRD was performed using a high-resolution diffractometer (Bruker AXS D8 Advance X-Ray Diffractometer) with Cu Kα radiation (λ=1.5406 Å) with a scan speed of 0.3 s/step, 0.02°/step in the range of 5° ˜50°. UV-vis spectra were obtained using a homemade spectrophotometer system based on Ocean Optics USB4000 miniature fiber optic spectrometer. The light was provided by OSLI-EC-High-Intensity Fiber Light Source, then passed through a fiber attenuator (FVA-UV, Wy Optics, China) to control the luminous flux between fibers. Time-resolved photoluminescence (TRPL) and steady-state photoluminescence were measured using a 375 nm picosecond laser (PicoQuant LDH-D-C-375) as the excitation. The PL signal was directed into a spectrograph (Ando Kymera 328i) and further collected by an electron-multiplying charge-coupled device (EMCCD; Andor iXon Life 888) for steady-state PL and a streak camera (Hamamatsu C10910) for TRPL. The top-view and cross-sectional microstructures of the thin films were observed using a scanning electron microscope (Carl Zeiss: LEO 1530). All the measurements were performed under ambient conditions.

### Example 4—Mechanical Behaviour Testing

For film delamination testing, the sandwich specimen structure ITO/SnO₂/perovskite/PMMA/Epoxy/Glass has been applied to measure mechanical properties. The SnO₂ with and without homo-/hetero-CPI has been deposited on the indium tin oxide coated glasses, then the perovskite layers (˜300 nm) respectively deposited on the SnO₂ (FA_{0.9}Cs_{0.1}PbI₃ perovskite precursor for SnO₂ sample, FA_{0.9}Cs_{0.1}PbI₃ with 4% PbI₂ excess perovskite precursor for the homo-/hetero-CPI. The PMMA layer was coated onto the perovskite layer for protection via spin coating (6000 rpm, 60 s). To glue another cleaned glass substrate onto the PMMA layer, a thin epoxy layer (Deli 7148 #AB glue) of about 2 μm was applied. After the glue has cured for 24 hours, the perovskite can be delaminated by adding an external force. The effective area of the sample is 1.5 cm². Stress-displacement curves are acquired by using a double-cantilever beam delamination technique. The sample fabrication is the same as that for the film delamination testing. Before epoxy application, a 3-mm strip is masked near the edge of the PMMA layer to create a notch. After that, adhesive was used to attach the test specimens to the upper and lower clevis. The glass piece and the clevis' bonding surface are washed with alcohol and allowed to dry before applying the adhesive bonding. The fixture is constructed from an aluminium alloy. The sample is a square piece with sides that are 15 mm long, and to activate the adhesive, the glass piece is pressed against the sample for 30 seconds at a 100 N force. The stress is determined by the greatest load per unit bonded area after the glue has been attached to the glass piece and before the tensile force is passed to the bonding surface through the specimen's longitudinal axis until it is destroyed.

### Example 5—DFT Calculation

The first-principles computations are performed based on density-functional theory (DFT) methods as implemented in the Vienna ab initio simulation package (VASP). An energy cutoff of 500 eV is employed. Structural geometry optimization was performed using Perdew-Burke-Ernzerhof exchange-correlation functional and with energy convergence and force convergence of 10⁻⁴ eV and 0.02 eV Δ⁻¹, respectively. Grimme's DFT-D3 correction is adopted to describe the long-range van der Waals interaction. The Γ-centered k-meshes with the k-spacing of 0.3 Å⁻¹ were employed to sample the Brillouin zone for the total energy calculation. We used a 2×2 supercell of (001)-plane rutile SnO₂ surfaces. The slab consists of five symmetric layers of SnO₂ with FA⁺, R-MBA⁺, R/S-MBA⁺ absorbing on the surface for pristine, homo- and hetero-CPI, respectively. Each model was built with a vacuum size of about 15 Å.

### Example 6—Space Charge Limited Current (SCLC) Measurement

For SCLC testing, the specimen structure ITO/SnO₂/perovskite/PCBM/Ag has been synthesized. The SnO₂ with and without homo-/hetero-CPI has been deposited on the indium tin oxide coated glasses, then the perovskite layers (˜300 nm) respectively deposited on the SnO₂ (FA_{0.9}Cs_{0.1}PbI₃ perovskite precursor for SnO₂ sample, FA_{0.9}Cs_{0.1}PbI₃ with 4% PbI₂ excess perovskite precursor for the homo-/hetero-CPI. The 20 mg/mL PCBM in CB was spin-coated onto the perovskite layer as HTL (4000 rpm, 30 s). Ag (80 nm) was deposited as electrodes using thermal evaporation method. The relative trap density (Nₜᵣₐₚ) was calculated according to the following equation:

$${N}_{trap} = ( 2 {εε}_{0} {V}_{TFL} ) / ( {eL}^{2} ) ,$$

where ε₀ and ε are the vacuum permittivity and the dielectric constant of the OIHP film, respectively; L is the thickness of the OIHP film; and e is the elementary charge. The trap-filled limit voltage (V_{TFL}) refers to the voltage that results when the trap states are fully filled and the current increases significantly.

### Example 6—Solar Cell Fabrication and Testing

N-i-p perovskite solar cells (PSCs) were fabricated using the following steps. The fluorine-doped tin oxide ITO-coated glass was pre-cleaned successively in ultrasonic baths of detergent solution, deionized water, ethanol, acetone, and isopropanol, for 30 min each, and further treated with UV-ozone for 15 min. A dilute SnO₂ nanoparticle solution (IPA:Water:SnO₂ nanoparticle solution directly from Alfa Aesar=3:3:1) was spin-coated onto the substrates at 3000 rpm for 30 s and annealed at 150° C. for 30 mins to form a compact SnO₂ electron-transport layer. Precursor solution was prepared by dissolving PbI₂ (0.5827 g), MABr (0.0071 g), PbBr₂ (0.0232 g), MACl (0.030 g), and FAI (0.2173 g) in DMF (0.8 ml) and DMSO (0.1 ml) with different molar amounts (0%, 1%, 2%, 4%) of OAT. CPI was fabricated through a modified procedure by adding 5 mg R- or R/S-MBAI in 1 mL dilute SnO₂ nanoparticle solution. The perovskite layer is deposited by spin-coating at 500 rpm 5 s, then 1000 rpm 5 s, then 2750 rpm 20 s (last 5 s, gently and consistently dripping 1 ml DEE by using the specialized 1 ml displacement DEE gun). Subsequently, the as-deposited films were annealed at 120° C. for 40 min. The Spiro-OMeTAD solution was prepared by dissolving 72.5 mg of Spiro-OMeTAD with additives in 1000 μL of CB. 17.5 μL of Li-TFSI solution (520 mg·mL⁻¹ in ACN), and 29.5 μL of TBP were added to the solution. The Spiro-OMeTAD hole-transport layer (HTL) was prepared by spin-coating the solution at 3000 rpm for 30 s. Both perovskite and HTL deposition were performed in a humidity-controlled (˜15% RH) hood. Finally, 80 nm of Ag layer was thermally evaporated on top of the HTL as an electrode.

P-i-n PSCs were fabricated with the following steps. The patterned transparent conducting oxide glass substrates (FTO) were washed with acetone and isopropanol for 15 min each. After ultraviolet ozone treatment for 15 min, a 0.5 mg ml⁻¹ MeO-2PACz self-assembled monolayer solution dissolved in ethanol was spin-coated on substrates at 3,000 rpm for 30 s in a nitrogen glovebox, followed by annealing at 100° C. for 10 min. The 1.55 M perovskite precursor solution was used for preparing perovskite films. For fabrication of the perovskite film, the substrate was spun at 1000 rpm. for 10 s with an initial acceleration of 200 rpm, and then at 5000 rpm for 30 s with an acceleration of 1000 rpm per second. In the second step, CB antisolvent (200 μl) was added dropwise onto the substrate during the last 15 s of spinning. The substrate was immediately placed on a hotplate and annealed at 100° C. for 30 min. For the surface treatment, the CPIs were prepared by dissolving the 2D ligand salts (R- or R/S-MBAI) with MAI and DMF in IPA. The ligand salt (1 mg ml⁻¹), MAI (0.5 mg ml⁻¹) and an IPA:DMF v/v ratio of 1:200 was used. Afterwards, samples were transferred to an Angstrom evaporator for/C₆₀ (25 nm)/BCP (6 nm)/Ag (100 nm) deposition. The device area by evaporation was 0.112 cm². Unless otherwise stated, the devices were masked with metal aperture masks (0.059 cm²) during the J-V measurement.

The current density-voltage (J-V) characterization for PSCs was measured by a source meter (2612, Keithley, USA) at the scan rate of 100 mV s⁻¹ under stimulated AM 1.5 G one-sun illumination (100 mW cm⁻²) generated by a solar simulator (Sirius-SS, Zolix, China). The intensity was calibrated using a standard Si reference cell. Steady-state current/PCE outputs were measured using a 2612B Source Meter (Keithley, USA) at voltages determined from the MPPs of the reverse-scan J-V curves. For light-soaking stability tests, unencapsulated PSCs were placed in a sealed quartz cell holder in an N₂-filled glovebox under a one-sun-intensity while-LED illumination. For operational stability tests, PSCs were biased at the maximum-power-point voltage using a potentiostat under continuous one-sun-intensity white-LED illumination at around 50° C. For damp heat tests, encapsulated PSCs are placed under a controlled humidity of 85% RH and temperature of 85° C. The Thermal Cycling test according to IEC 61215 uses 200 cycles of temperatures between −40° C. to 85° C. with a 42° C./h rate and 20 min stabilizing process at −40° C. and 85° C. The Thermal Cycling test of extreme temperatures (−195° C. and 85° C.) was performed 15 cycles with 3 minutes stabilizing process at −195° C. and 85° C.

What is claimed is:

1. An electronic device comprising:
an electron-transport layer;
a chiral interface layer disposed on a surface of the electron-transport layer, wherein the chiral interface layer comprises a chiral compound, wherein the chiral compound is substantially enantiomerically pure or racemic; and
a perovskite layer disposed on a surface of the chiral interface layer; or
an electron-transport layer, wherein the electron-transport layer further comprises a chiral compound, wherein the chiral compound is substantially enantiomerically pure or racemic; and
a perovskite layer disposed on a surface of the electron-transport layer.

2. The electronic device of claim 1, wherein the chiral compound comprises one or more chiral centers, axial chirality, planar chirality, spiro chirality, helical chirality, or a combination thereof.

3. The electronic device of claim 1, wherein the chiral compound comprises one or more functional groups selected from the group consisting of alcohols, thiols, esters, acyls, thioacyls, amines, amides, ureas, carbamates, aldehydes, ketones, carboxylic acids, esters, carbonates, phosphines, phosphites, phosphates, halides, sulfoxides, sulfones, sulfonamides, and conjugate salts thereof.

4. The electronic device of claim 1, wherein the chiral compound is a chiral amine or a conjugate salt thereof.

5. The electronic device of claim 1, wherein the chiral compound is represented by a compound of Formula 1: 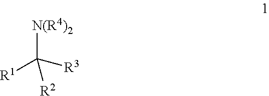
or a conjugate salt thereof, wherein each of R¹, R², and R³ are independently selected from the group consisting of hydrogen, alkyl, haloalkyl, perhaloalkyl, alkenyl, alkynyl, cycloalkyl, heterocycloalkyl, aryl, heteroaryl, and aralkyl; and
R⁴ for each instance is independently selected from the group consisting of hydrogen, alkyl, haloalkyl, perhaloalkyl, alkenyl, alkynyl, cycloalkyl, heterocycloalkyl, aryl, heteroaryl, and aralkyl; or two instances of R⁴ together with the atom they are covalently bonded form a 3-6 membered heterocyloalkyl, wherein R¹, R², and R³ are each different.

6. The electronic device of claim 5, wherein the chiral compound comprises a salt selected from the group consisting of chloride, bromide, iodide, formate, acetate, propionate, cyanide, cyanate, fulminate, thiocyanate, cyanamide, azide, tetrafluoroborate, hexafluorophosphate, and mixtures thereof.

7. The electronic device of claim 5, wherein R¹ is hydrogen.

8. The electronic device of claim 5, wherein R² is alkyl, haloalkyl, perhaloalkyl, alkenyl, or alkynyl; and R³ is alkyl, cycloalkyl, heterocycloalkyl, aryl, heteroaryl, or aralkyl.

9. The electronic device of claim 5, wherein R¹ is hydrogen; R² is alkyl; and R³ is cycloalkyl, aryl, or heteroaryl; or R¹ is hydrogen; R² is alkyl; and R³ is haloalkyl.

10. The electronic device of claim 5, wherein R¹ is hydrogen; R² is alkyl; and R³ is aryl; or R¹ is hydrogen; R² is alkyl; and R³ is haloalkyl.

11. The electronic device of claim 5, wherein R¹ is hydrogen; R² is methyl; and R³ is optionally substituted phenyl; or R¹ is hydrogen; R² is methyl; and R³ is trifluoromethyl.

12. The electronic device of claim 10, wherein R⁴ is hydrogen.

13. The electronic device of claim 1, wherein the chiral compound comprises (R)-α-methylbenzylammonium, (S)-α-methylbenzylammonium, (R)-2-ammonium-1,1,1-trifluoropropane, (S)-2-ammonium-1,1,1-trifluoropropane, racemic α-methylbenzylammonium, or racemic 2-ammonium-1,1,1-trifluoropropane.

14. The electronic device of claim 13, wherein the chiral compound comprises a salt selected from the group consisting of chloride, bromide, iodide, formate, acetate, propionate, cyanide, cyanate, fulminate, thiocyanate, cyanamide, azide, tetrafluoroborate, hexafluorophosphate, and mixtures thereof.

15. The electronic device of claim 1, wherein the perovskite layer comprises an organic-inorganic halide perovskite having the formula: (A⁺)(M²⁺)(X⁻)₃, wherein M²⁺ comprises Pb²⁺, Sn²⁺, Ge²⁺, or a mixture thereof; X⁻ is F⁻, Cl⁻, Br⁻, I⁻, or a mixture thereof; and A⁺ is Cs⁺, Rb⁺, CH₃NH₃_{⁺}, CH₃CH₂NH₃_{⁺}, H(C═NH₂)NH₂_{⁺}, Me(C═NH₂)NH₂_{⁺}, or a mixture thereof.

16. The electronic device of claim 13, wherein M²⁺ is Pb²⁺; A⁺ is Cs⁺ and Me(C═NH₂)NH₂_{⁺}; and X⁻ is I⁻.

17. The electronic device of claim 1, wherein the perovskite layer comprises an organic-inorganic halide perovskite having the formula: FA_{0.9}Cs_{0.1}PbI₃, wherein FA is Me(C═NH₂)NH₂_{⁺}.

18. The electronic device of claim 1, wherein the perovskite layer further comprises PbI₂.

19. The electronic device of claim 1, wherein the electron-transport layer comprises PC₆₁BM, bathocuproine, C₆₀, SnO₂, or a mixture thereof.

20. The electronic device of claim 1, wherein the chiral compound comprises (R)-α-methylbenzylammonium iodide, (S)-α-methylbenzylammonium iodide, (R)-2-ammonium-1,1,1-trifluoropropane iodide, (S)-2-ammonium-1,1,1-trifluoropropane iodide, racemic α-methylbenzylammonium iodide, or racemic 2-ammonium-1,1,1-trifluoropropane iodide; the perovskite layer comprises an organic-inorganic halide perovskite having the formula: FA₍₁₋ₓ₎CsₓPbI₃, wherein x is 0.01-0.99 and FA is Me(C═NH₂)NH₂_{⁺}; and the electron-transport layer comprises SnO₂.

21. The electronic device of claim 1 further comprising:
a metal electrode disposed on a surface of the electron-transport layer;
a hole-transport layer disposed on a surface of the perovskite layer;
a transparent conductive layer disposed on a surface of the hole-transport layer; and
a substrate layer disposed on a surface of the transparent conductive layer; or
a hole-transport layer disposed on a surface of the perovskite layer;
a transparent conductive layer disposed on a surface of the hole-transport layer;
a substrate layer disposed on a surface of the transparent conductive layer; and
a metal electrode disposed on a surface of the electron-transport layer.

22. The electronic device of claim 21, wherein the electron-transport layer comprises SnO₂; the hole-transport later comprises N²,N²,N^{2′},N^{2′},N⁷,N⁷,N^{7′},N^{7′}-octakis(4-methoxyphenyl)-9,9′-spirobi[9H-fluorene]-2,2′,7,7′-tetramine (Spiro-OMeTAD), and transparent conductive layer comprises indium tin oxide (ITO).
